(19) United States
(12) Patent Application Publication
(10) Pub. No.: US 2026/0247715 A1
(43) Pub. Date: Aug. 20, 2026

(54) DISPLAY PANEL AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Tiaomei ZHANG, Beijing (CN); Ziyang YU, Beijing (CN); Quanyong GU, Beijing (CN); Wenhui GAO, Beijing (CN); Dan CAO, Beijing (CN); Zhiliang JIANG, Beijing (CN); Ming HU, Beijing (CN); Wenbo CHEN, Beijing (CN); Mengqi WANG, Beijing (CN); Shilong WANG, Beijing (CN); Yujing LI, Beijing (CN); Ge NIU, Beijing (CN); Erjin ZHAO, Beijing (CN); Pan ZHAO, Beijing (CN); Jianpeng WU, Beijing (CN); Tianyi CHENG, Beijing (CN); Jingwen ZHANG, Beijing (CN); Yonglin GUO, Beijing (CN); Gukhwan SONG, Beijing (CN); Hai ZHENG, Beijing (CN); Haigang QING, Beijing (CN); Xiangdan DONG, Beijing (CN); Yi ZHANG, Beijing (CN); Rui WANG, Beijing (CN); Taofeng XIE, Beijing (CN); Haijun QIU, Beijing (CN)

(21) Appl. No.: 19/469,530

(22) PCT Filed: Apr. 27, 2023
(86) PCT No.: PCT/CN2023/091253

§ 371 Date: Sep. 26, 2025

(51) Int. Cl. H10D 86/40; H10D 86/60

(52) U.S. Cl. CPC H10D 86/441; H10D 86/60

(57) ABSTRACT

A display panel, includes: a base substrate; a plurality of first initial signal lines, wherein orthographic projections of the first initial signal lines on the base substrate extend along a first direction and are spaced apart along a second direction, and the first direction intersects with the second direction; a plurality of second initial signal lines, located in a same conductive layer as the first initial signal lines, wherein orthographic projections of the second initial signal lines on the base substrate extend along the first direction and are spaced apart along the second direction; a plurality of first initial connection lines; and a plurality of second initial connection lines.

### TECHNICAL FIELD

The present disclosure relates to the field of display technology, and in particular, to a display panel and a display device.

### BACKGROUND

In the related art, display panels have problems such as poor display uniformity and low-frequency flicker.

It should be noted that the information disclosed in the above background technology section is only used to enhance understanding the background of the present disclosure, and therefore may include information that does not constitute the prior art known to those skilled in the art.

### SUMMARY

According to an aspect of this disclosure, a display panel is provided and includes: a base substrate, a plurality of first initial signal lines, a plurality of second initial signal lines, a plurality of first initial connection lines, and a plurality of second initial connection lines. Orthographic projections of the first initial signal lines on the base substrate extend along a first direction and are spaced apart along a second direction, where the first direction intersects with the second direction. The second initial signal lines are located in a same conductive layer as the first initial signal lines, and orthographic projections of the second initial signal lines on the base substrate extend along the first direction and are spaced apart along the second direction. The first initial connection lines are located in a different conductive layer from the first initial signal lines, where orthographic projections of the first initial connection lines on the base substrate extend along the second direction and are spaced apart along the first direction, and the first initial connection lines are connected, through vias, to at least part of the first initial signal lines with orthographic projections on the base substrate intersecting with the first initial connection lines. The second initial connection lines are located in a same conductive layer as the first initial connection lines, where orthographic projections of the second initial connection lines on the base substrate extend along the second direction and are spaced apart along the first direction, and the second initial connection lines are connected, through vias, to at least part of the second initial signal lines with orthographic projections on the base substrate intersecting with the second initial connection lines.

In an exemplary embodiment of this disclosure, the display panel further includes: a second conductive layer and a third conductive layer. The second conductive layer is located on a side of the base substrate, and includes the first initial signal lines and the second initial signal lines. The third conductive layer is located on a side of the second conductive layer away from the base substrate, and includes the first initial connection lines and the second initial connection lines.

In an exemplary embodiment of this disclosure, the display panel further includes: a pixel driving circuit, where the pixel driving circuit includes a driving transistor, a first transistor, and a capacitor. A first electrode of the capacitor is connected to a gate of the driving transistor, a first electrode of the first transistor is connected to the first initial signal line, and a second electrode of the first transistor is connected to the gate of the driving transistor. The display panel further includes: a first conductive layer, located between the second conductive layer and the base substrate, where the first conductive layer includes a first conductive portion, and the first conductive portion is configured to form the gate of the driving transistor and the first electrode of the capacitor. The second conductive layer further includes: a second conductive portion, where an orthographic projection of the second conductive portion on the base substrate at least partially overlaps with an orthographic projection of the first conductive portion on the base substrate, and the second conductive portion is configured to form a second electrode of the capacitor. The third conductive layer further includes: a first bridge portion, where the first bridge portion is connected to the second electrode of the first transistor, and is connected to the first conductive portion through a via.

In an exemplary embodiment of this disclosure, the display panel further includes: a pixel driving circuit, where the pixel driving circuit includes a driving transistor, a fourth transistor, and a second transistor. The fourth transistor is provided with a first electrode connected to a data line, a second electrode connected to a first electrode of the driving transistor, and a gate connected to a second reset signal line. The second transistor is provided with a first electrode connected to a gate of the driving transistor, a second electrode connected to a second electrode of the driving transistor, and a gate connected to a gate line.

In an exemplary embodiment of this disclosure, the display panel further includes: a pixel driving circuit, where the pixel driving circuit includes a driving transistor and a second transistor. A first electrode of the second transistor is connected to a gate of the driving transistor, and a second electrode of the second transistor is connected to a second electrode of the driving transistor. The display panel further includes: an active layer and a second conductive layer. The active layer is located on a side of the base substrate, and includes a second active portion configured to form a channel region of the second transistor, where the second active portion includes a first active sub-portion and a second active sub-portion, and the active layer further includes a third active sub-portion connected between the first active sub-portion and the second active sub-portion. The second conductive layer is located on a side of the active layer away from the base substrate, and includes a third conductive portion, where an orthographic projection of the third conductive portion on the base substrate at least partially overlaps with an orthographic projection of the third active sub-portion on the base substrate, and the third conductive portion is connected to a stable voltage source.

In an exemplary embodiment of this disclosure, the first active sub-portion serving as a channel region includes a first side extending along a length direction of the channel region, the second active sub-portion serving as a channel region includes a second side extending along a length direction of the channel region, and the third active sub-portion includes a third side and a fourth side. The third side is connected to the first side, and an angle formed by the third side and the first side is less than or equal to 180°; and/or, the fourth side is connected to the second side, and an angle formed by the fourth side and the second side is less than or equal to 180°.

In an exemplary embodiment of this disclosure, the display panel further includes: a power line, configured to provide a power signal to the pixel driving circuit, where the power line is connected to the third conductive portion through a via.

In an exemplary embodiment of this disclosure, the second conductive layer includes the first initial signal line, and the first initial signal line and the third conductive portion are connected in the same layer.

In an exemplary embodiment of this disclosure, the pixel driving circuit further includes a capacitor, and a first electrode of the capacitor is connected to the gate of the driving transistor. The second conductive layer further includes: a second conductive portion, configured to form a second electrode of the capacitor. The third conductive portion and the second conductive portion are connected in the same layer.

In an exemplary embodiment of this disclosure, the display panel further includes: pixel driving circuits arrayed in the first direction and the second direction, the pixel driving circuit includes a driving transistor and a capacitor, and a first electrode of the capacitor is connected to a gate of the driving transistor. The display panel further includes: a second conductive layer and a third conductive layer. The second conductive layer includes a second conductive portion and a fourth conductive portion, where the second conductive portion is configured to form a second electrode of the capacitor, and the fourth conductive portion is connected between second conductive portions adjacent to each other in the first direction. The third conductive layer is located on a side of the second conductive layer away from the base substrate, and includes a power line, where the power line is configured to provide a power signal to the pixel driving circuit. The power line includes: a first extension portion, a second extension portion, and a third extension portion, and the third extension portion is connected between the first extension portion and the second extension portion. An orthographic projection of the first extension portion on the base substrate and an orthographic projection of the second extension portion on the base substrate extend along the second direction, and an orthographic projection of the third extension portion on the base substrate extends along the first direction. The orthographic projection of the third extension portion on the base substrate at least partially overlaps with an orthographic projection of the fourth conductive portion on the base substrate.

In an exemplary embodiment of this disclosure, the display panel further includes: a fourth conductive layer, located on a side of the third conductive layer away from the base substrate, where the fourth conductive layer includes a plurality of data lines, and orthographic projections of the data lines on the base substrate extend along the second direction. Orthographic projections of part of the data lines on the base substrate at least partially overlap with the orthographic projections of the first initial connection lines on the base substrate; and/or, orthographic projections of part of the data lines on the base substrate at least partially overlap with the orthographic projections of the second initial connection lines on the base substrate.

In an exemplary embodiment of this disclosure, among the data lines and the first initial connection lines with overlapped orthographic projections on the base substrate, an overlapping area between the orthographic projections of the data lines on the base substrate and the orthographic projections of the first initial connection lines on the base substrate is S1, an area of the orthographic projections of the data lines on the base substrate is S2, and S1/S2 is greater than or equal to 50%; and/or, among the data lines and the second initial connection lines with overlapped orthographic projections on the base substrate, an overlapping area between the orthographic projections of the data lines on the base substrate and the orthographic projections of the second initial connection lines on the base substrate is S3, an area of the orthographic projections of the data lines on the base substrate is S4, and S3/S4 is greater than or equal to 50%.

In an exemplary embodiment of this disclosure, the display panel further includes: a pixel driving circuit. The third conductive layer further includes: a first connection portion and a plurality of power lines. An orthographic projection of the first connection portion on the base substrate extends along the first direction, and the first connection portion is connected between the first initial connection line and the pixel driving circuit. The power lines are configured to provide a power signal to the pixel driving circuit. Part of the power lines include multiple power line segments spaced apart in the second direction, and the orthographic projection of the first connection portion on the base substrate is located between orthographic projections, on the base substrate, of adjacent power line segments in a same power line.

In an exemplary embodiment of this disclosure, the display panel further includes: a third conductive layer, a fourth conductive layer, an electrode layer and a pixel definition layer. The third conductive layer is located on a side of the base substrate. The fourth conductive layer is located on a side of the third conductive layer away from the base substrate, and a partial structure of the fourth conductive layer is connected to a partial structure of the third conductive layer through a via. The electrode layer is located on a side of the fourth conductive layer away from the base substrate, and includes a plurality of electrode portions. The pixel definition layer is located on a side of the electrode layer away from the base substrate, and a plurality of pixel openings are formed on the pixel definition layer and arranged corresponding to the electrode portions, where orthographic projections of the pixel openings on the base substrate coincide with orthographic projections of the corresponding electrode portions on the base substrate. An orthographic projection of the via connected between the third conductive layer and the fourth conductive layer on the base substrate does not overlap with the orthographic projections of the electrode portions on the base substrate.

In an exemplary embodiment of this disclosure, the display panel further includes: a fourth conductive layer, an electrode layer and a pixel definition layer. The fourth conductive layer is located on a side of the base substrate, and includes a plurality of fifth bridge portions. The electrode layer is located on a side of the fourth conductive layer away from the base substrate, and includes a plurality of electrode portions arranged corresponding to the fifth bridge portions, where the electrode portions are connected to the corresponding fifth bridge portions through vias. The pixel definition layer is located on a side of the electrode layer away from the base substrate, and a plurality of pixel openings are formed on the pixel definition layer and arranged corresponding to the electrode portions, where orthographic projections of the pixel openings on the base substrate coincide with orthographic projections of the corresponding electrode portions on the base substrate. The fourth conductive layer further includes a sixth conductive portion, where orthographic projections of part of the electrode portions on the base substrate overlap with an orthographic projection of the sixth conductive portion on the base substrate and an orthographic projection of the fifth bridge portion on the base substrate respectively. The orthographic projection of the sixth conductive portion on the base substrate is arranged close a side, in the first direction, of the orthographic projection of the electrode portion on the base substrate, and the orthographic projection of the fifth bridge portion on the base substrate is arranged on another side, in the first direction, of the orthographic projection of the electrode portion on the base substrate.

In an exemplary embodiment of this disclosure, the display panel further includes a pixel driving circuit. The fourth conductive layer further includes: a power connection line, where an orthographic projection of the power connection line on the base substrate extends along the second direction, and the power connection line is configured to provide a power signal to the pixel driving circuit. The sixth conductive portion is connected to the power connection line, the orthographic projection of the power connection line on the base substrate is located between the orthographic projection of the sixth conductive portion on the base substrate and the orthographic projection of the fifth bridge part on the base substrate, and the orthographic projection of the power connection line on the base substrate overlaps with the orthographic projection of the electrode portion on the base substrate.

In an exemplary embodiment of this disclosure, the fifth bridge portion and the sixth conductive portion are connected.

In an exemplary embodiment of this disclosure, the display panel further includes a pixel driving circuit, where the pixel driving circuit includes a driving transistor, a fourth transistor, and a fifth transistor. A first electrode of the fourth transistor is connected to a data line, and a second electrode of the fourth transistor is connected to a first electrode of the driving transistor. A first electrode of the fifth transistor is connected to a power line, and a second electrode of the fifth transistor is connected to the first electrode of the driving transistor. The display panel further includes: an active layer and a first conductive layer. The active layer is located on a side of the base substrate, and includes a third active portion, a fourth active portion, and a fifth active portion. The third active portion is configured to form a channel region of the driving transistor, the fourth active portion is configured to form a channel region of the fourth transistor, and the fifth active portion is configured to form a channel region of the fifth transistor. The first conductive layer is located on a side of the active layer away from the base substrate, and includes a first conductive portion, a second reset signal line, and an enable signal line. An orthographic projection of the first conductive portion on the base substrate covers an orthographic projection of the third active portion on the base substrate, and the first conductive portion is configured to form a gate of the driving transistor. An orthographic projection of the second reset signal line on the base substrate extends along the first direction and covers an orthographic projection of the fourth active portion on the base substrate, and a partial structure of the second reset signal line is configured to form a gate of the fourth transistor. An orthographic projection of the enable signal line on the base substrate extends along the first direction and covers an orthographic projection of the fifth active portion on the base substrate, and a partial structure of the enable signal line is configured to form a gate of the fifth transistor. The orthographic projection of the enable signal line on the base substrate is located between the orthographic projection of the first conductive portion on the base substrate and the orthographic projection of the second reset signal line on the base substrate. In the first direction, the orthographic projection of the fifth active portion on the base substrate is located between an orthographic projection of at least a partial structure of the third active portion on the base substrate and the orthographic projection of the fourth active portion on the base substrate; or, in the first direction, the orthographic projection of the fourth active portion on the base substrate is located between an orthographic projection of at least a partial structure of the third active portion on the base substrate and the orthographic projection of the fifth active portion on the base substrate.

In an exemplary embodiment of this disclosure, a square resistance of the second conductive layer is greater than a square resistance of the third conductive layer, and the display panel further includes: a first initial routing line and a second initial routing line. Orthographic projections of the first initial routing line and the second initial routing line on the base substrate extend along the first direction, and are located on a side, in the second direction, of the orthographic projections of the first initial connection line and the second initial connection line on the base substrate. The first initial routing line connects multiple first initial connection lines, and the second initial routing line connects multiple second initial connection lines.

In an exemplary embodiment of this disclosure, the display panel further includes a pixel driving circuit and a gate driving circuit. The orthographic projection of the second initial routing line on the base substrate is located on a side of the orthographic projection of the first initial routing line on the base substrate away from the orthographic projections of the first initial connection line and the second initial connection line on the base substrate. The third conductive layer further includes: a plurality of gate line access lines, where orthographic projections of the gate line access lines on the base substrate extend along the first direction and are spaced apart along the second direction, and the gate line access lines are connected between the gate driving circuit and the pixel driving circuit. The orthographic projections of the first initial routing line and the second initial routing line on the base substrate are located between orthographic projections, on the base substrate, of two adjacent gate line access lines.

In an exemplary embodiment of this disclosure, the display panel further includes a gate driving circuit and a plurality of pixel driving circuits. The display panel further includes: a fourth conductive layer, an electrode layer and a pixel definition layer. The fourth conductive layer is located on a side of the base substrate, and includes a plurality of data lines, where the data lines are configured to provide data signal to the pixel driving circuits, and orthographic projections of the data lines on the base substrate extend along the second direction and are spaced apart along the first direction. The electrode layer is located on a side of the fourth conductive layer away from the base substrate, and includes a plurality of electrode portions. The pixel definition layer is located on a side of the electrode layer away from the base substrate, and a plurality of pixel openings are formed on the pixel definition layer and are arranged corresponding to the electrode portions, where an orthographic projection of a pixel opening on the base substrate coincide with an orthographic projection of a corresponding electrode portion on the base substrate. An orthographic projection of part of the electrode portions on the base substrate overlap with orthographic projections, on the base substrate, of two data lines adjacent in the first direction, and the orthographic projections, on the base substrate, of the two data lines adjacent in the first direction are respectively arranged close to two sides, in the first direction, of the orthographic projection of an overlapping electrode portion on the base substrate. The fourth conductive layer further includes: an analog data line, where an orthographic projection of the analog data line on the base substrate extends along the second direction, and is located between an orthographic projection of the gate driving circuit on the base substrate and an orthographic projection of a data line closest to the gate driving circuit on the base substrate. Orthographic projections, on the base substrate, of the analog data line and a data line adjacent to the analog data line overlap with an orthographic projection of an electrode portion on the base substrate. In the first direction, the orthographic projections, on the base substrate, of the analog data line and the data line adjacent to the analog data line are respectively arranged close to two sides, in the first direction, of the orthographic projection of the overlapping electrode portion on the base substrate.

In an exemplary embodiment of this disclosure, the display panel further includes a first initial routing line and a second initial routing line. Orthographic projections of the first initial routing line and the second initial routing line on the base substrate extend along the first direction, and are located on a side, in the second direction, of the orthographic projections of the first initial connection line and the second initial connection line on the base substrate. The first initial routing line connects multiple first initial connection lines, and the second initial routing line connects multiple second initial connection lines. The orthographic projection of the second initial routing line on the base substrate is located on a side of the orthographic projection of the first initial routing line on the base substrate away from the orthographic projections of the first initial connection line and the second initial connection line on the base substrate. The second initial signal line is connected to the analog data line, and the analog data line is connected to the plurality of second initial signal lines through a via.

This disclosure further provides a display panel, including: a base substrate, a plurality of first initial signal lines, a plurality of second initial signal lines, a plurality of first initial connection lines, a plurality of second initial connection lines and a plurality of pixel driving circuits. Orthographic projections of the first initial signal lines on the base substrate extend along a first direction and are spaced apart along a second direction, where the first direction intersects with the second direction. The second initial signal lines are located in a same conductive layer as the first initial signal lines, where orthographic projections of the second initial signal lines on the base substrate extend along the first direction and are spaced apart along the second direction ;. The first initial connection lines are located in a different conductive layer from the first initial signal lines, where orthographic projections of the first initial connection lines on the base substrate extend along the second direction and spaced apart along the first direction, and the first initial connection lines are connected to at least part of the first initial signal lines with orthographic projections on the base substrate intersecting with the first initial connection lines. The second initial connection lines are located in a same conductive layer as the first initial connection lines, where orthographic projections of the second initial connection lines on the base substrate extend along the second direction and are spaced apart along the first direction, and the second initial connection lines are connected to at least part of the second initial signal lines with orthographic projections on the base substrate intersecting with the second initial connection lines. The pixel driving circuits are arranged in an array along the first direction and the second direction, where the first direction is a row direction and the second direction is a column direction. Each row of the pixel driving circuits is correspondingly provided with one first initial signal line and one second initial signal line, and each column of the pixel driving circuits is correspondingly provided with one first initial connection line or one second initial connection line. The orthographic projections of the first initial connection lines on the base substrate and the orthographic projections of the second initial connection lines on the base substrate are alternately distributed in sequence in the first direction.

In an exemplary embodiment of this disclosure, the display panel further includes a pixel driving circuit and a light emitting unit, where the pixel driving circuit includes: a driving transistor, a first transistor, a second transistor, a fourth transistor, a fifth transistor, a sixth transistor, a seventh transistor, and a capacitor. The first transistor is provided with a first electrode connected to the first initial signal line, a second electrode connected to a gate of the driving transistor, and a gate connected to a first reset signal line. The second transistor is provided with a first electrode connected to the gate of the driving transistor, a second electrode connected to a second electrode of the driving transistor, and a gate connected to a gate line. The fourth transistor is provided with a first electrode connected to a data line, a second electrode connected to a first electrode of the driving transistor, and a gate connected to a second reset signal line. The fifth transistor is provided with a first electrode connected to a power line, a second electrode connected to the first electrode of the driving transistor, and a gate connected to an enable signal line. The sixth transistor is provided with a first electrode connected to the second electrode of the driving transistor, a second electrode connected to the first electrode of the light emitting unit, and a gate connected to the enable signal line. The seventh transistor is provided with a first electrode connected to the second initial signal line, a second electrode connected to the first electrode of the light emitting unit, and a gate connected to the second reset signal line. The capacitor is provided with a first electrode connected to the gate of the driving transistor, and a second electrode connected to the power line.

In an exemplary embodiment of this disclosure, the display panel further includes: an active layer and a first conductive layer. The active layer is located on a side of the base substrate, and a partial structure of the active layer is configured to form channel regions of the first transistor, the second transistor, the driving transistor, the fourth transistor, the fifth transistor, the sixth transistor, and the seventh transistor, respectively. The first conductive layer is located on a side of the active layer away from the base substrate, and includes a first conductive portion, the first reset signal line, the second reset signal line, and the enable signal line. The first conductive portion is configured to form the gate of the driving transistor, a partial structure of the first reset signal line is configured to form the gate of the first transistor, a partial structure of the second reset signal line is configured to form the gates of the fourth transistor and the seventh transistor, respectively, and a partial structure of the enable signal line is configured to form the gates of the fifth transistor and the sixth transistor, respectively. An orthographic projection of the first conductive portion on the base substrate is located between an orthographic projection of the first reset signal line on the base substrate and an orthographic projection of the enable signal line on the base substrate. An orthographic projection of the second reset signal line on the base substrate is located on a side of the orthographic projection of the enable signal line on the base substrate away from the orthographic projection of the first conductive portion on the base substrate.

According to an aspect of this disclosure, a display device is provided and includes the display panel as described above.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. The accompanying drawings described below are only some embodiments of the present disclosure, and for those skilled in the art, other accompanying drawings can be obtained based on these accompanying drawings without creative work.

FIG. 1 is a schematic structural diagram of a pixel driving circuit according to an exemplary embodiment of this disclosure.

FIG. 2 is a timing diagram of signals on each node in a driving method of the pixel driving circuit shown in FIG. 1.

FIG. 3 is a structural layout of a display panel according to another exemplary embodiment of this disclosure.

FIG. 4 is a structural layout of the active layer in FIG. 3.

FIG. 5 is a structural layout of the first conductive layer in FIG. 3.

FIG. 6 is a structural layout of the second conductive layer in FIG. 3.

FIG. 7 is a structural layout of the third conductive layer in FIG. 3.

FIG. 8 is a structural layout of the fourth conductive layer in FIG. 3.

FIG. 9 is a structural layout of the electrode layer in FIG. 3.

FIG. 10 is a structural layout of the active layer and the first conductive layer in FIG. 3.

FIG. 11 is a structural layout of the active layer, the first conductive layer, and the second conductive layer in FIG. 3.

FIG. 12 is a structural layout of the active layer, the first conductive layer, the second conductive layer, and the third conductive layer in FIG. 3.

FIG. 13 is a structural layout of the active layer, the first conductive layer, the second conductive layer, the third conductive layer, and the fourth conductive layer in FIG. 3.

FIG. 14 is a structural layout of a display panel according to an exemplary embodiment of this disclosure.

FIG. 15 is a structural layout of the third conductive layer in FIG. 14.

FIG. 16 is a structural layout of the fourth conductive layer in FIG. 14.

FIG. 17 is a structural diagram of the electrode layer in FIG. 14.

FIG. 18 is a structural layout of the third conductive layer and the fourth conductive layer in FIG. 14.

FIG. 19 is a partial cross-sectional view, taken along the dotted line AA, of the display panel shown in FIG. 3.

FIG. 20 is a structural layout of a display panel according to another exemplary embodiment of this disclosure.

FIG. 21 is a structural layout of the active layer in FIG. 20.

FIG. 22 is a structural layout of the first conductive layer in FIG. 20.

FIG. 23 is a structural layout of the second conductive layer in FIG. 20.

FIG. 24 is a structural layout of the third conductive layer in FIG. 20.

FIG. 25 is a structural layout of the fourth conductive layer in FIG. 20.

FIG. 26 is a structural layout of the electrode layer in FIG. 20.

FIG. 27 is a structural layout of the active layer and the first conductive layer in FIG. 20.

FIG. 28 is a structural layout of the active layer, the first conductive layer, and the second conductive layer in FIG. 20.

FIG. 29 is a structural layout of the active layer, the first conductive layer, the second conductive layer, and the third conductive layer in FIG. 20.

FIG. 30 is a structural layout of the active layer, the first conductive layer, the second conductive layer, the third conductive layer, and the fourth conductive layer in FIG. 20.

FIG. 31 is a structural diagram of a display panel according to another exemplary embodiment of this disclosure.

FIG. 32 is a structural layout of the third conductive layer in FIG. 31.

FIG. 33 is a structural layout of the fourth conductive layer in FIG. 31.

FIG. 34 is a structural diagram of the electrode layer in FIG. 31.

FIG. 35 is a structural layout of the third conductive layer and the fourth conductive layer in FIG. 31.

FIG. 36 is a structural diagram of a display panel according to another exemplary embodiment of this disclosure.

FIG. 37 is a structural layout of the active layer in FIG. 36.

FIG. 38 is a structural layout of the first conductive layer in FIG. 36.

FIG. 39 is a structural layout of the second conductive layer in FIG. 36.

FIG. 40 is a structural layout of the third conductive layer in FIG. 36.

FIG. 41 is a structural layout of the fourth conductive layer in FIG. 36.

FIG. 42 is a structural layout of the active layer and the first conductive layer in FIG. 36.

FIG. 43 is a structural layout of the active layer, the first conductive layer, and the second conductive layer in FIG. 36.

FIG. 44 is a structural layout of the active layer, the first conductive layer, the second conductive layer, and the third conductive layer in FIG. 36.

FIG. 45 is a schematic structural diagram of a display panel according to an exemplary embodiment of this disclosure.

FIG. 46 is an enlarged view of a local area C in FIG. 45.

FIG. 47 is a structural layout of the third conductive layer in FIG. 46.

FIG. 48 is a structural layout of the fourth conductive layer in FIG. 46.

FIG. 49 is an enlarged view of a local area D in FIG. 45.

FIG. 50 is an enlarged view of the local area E in FIG. 45.

### DETAILED DESCRIPTION

Exemplary embodiments will now be described more fully with reference to the accompanying drawings. However, exemplary embodiments can be implemented in a variety of forms and should not be construed as limited to the embodiments set forth herein. Rather, these embodiments are provided so that the present disclosure will be comprehensive and complete, and fully convey the concepts of the exemplary embodiments to those skilled in the art. The same reference numerals in the drawings represent the same or similar structures, and thus their detailed description will be omitted.

The terms “a”, “an”, and “said” are used to indicate the presence of one or more elements/components/etc.; the terms “comprise” and “have” are used to indicate an open-ended inclusive meaning and mean that additional elements/components/etc. may be present in addition to the listed elements/components/etc.

Some exemplary embodiments first provide a pixel driving circuit, as shown in FIG. 1, which is a schematic diagram of the pixel driving circuit according to an exemplary embodiment of the present disclosure. The pixel driving circuit may include: a driving transistor T3, a first transistor T1, a second transistor T2, a fourth transistor T4, a fifth transistor T5, a sixth transistor T6, a seventh transistor T7, and a capacitor C. Herein, the first electrode of the fourth transistor T4 is connected to the data signal terminal Da, the second electrode of the fourth transistor T4 is connected to the first electrode of the driving transistor T3, and the gate of the fourth transistor T4 is connected to the second reset signal terminal Re2. The first electrode of the fifth transistor T5 is connected to the first power supply terminal VDD, the second electrode of the fifth transistor T5 is connected to the first electrode of the driving transistor T3, and the gate of the fifth transistor T5 is connected to the enable signal terminal EM. The gate of the driving transistor T3 is connected to the node N. The first electrode of the second transistor T2 is connected to the node N, the second electrode of the second transistor T2 is connected to the second electrode of the driving transistor T3, and the gate of the second transistor T2 is connected to the gate driving signal terminal Gate. The first electrode of the sixth transistor T6 is connected to the second electrode of the driving transistor T3, the second electrode of the sixth transistor T6 is connected to the second electrode of the seventh transistor T7, and the gate of the sixth transistor T6 is connected to the enable signal terminal EM. The first electrode of the seventh transistor T7 is connected to the second initial signal terminal Vinit2, and the gate of the seventh transistor T7 is connected to the second reset signal terminal Re2. The second electrode of the first transistor T1 is connected to the node N, the first electrode of the first transistor T1 is connected to the first initial signal terminal Vinit1, and the gate of the first transistor T1 is connected to the first reset signal terminal Re1. The first electrode of the capacitor C is connected to the node N, and the second electrode of the capacitor C is connected to the first power supply terminal VDD. The pixel driving circuit can be connected to a light-emitting unit OLED, and the pixel driving circuit is used to drive the light-emitting unit OLED to emit light. The first electrode of the light-emitting unit OLED can be connected to the second electrode of the sixth transistor T6, and the second electrode of the light-emitting unit can be connected to the second power supply terminal VSS. The first electrode of the light-emitting unit can be the anode of the light-emitting unit, and the second electrode of the light-emitting unit can be the cathode of the light-emitting unit. Herein, the first transistor T1, the second transistor T2, the driving transistor T3, the fourth transistor T4, the fifth transistor T5, the sixth transistor T6, and the seventh transistor T7 can be P-type transistors, which have a higher carrier mobility, thereby being conducive to realizing a display panel with high resolution, high response speed, high pixel density, and high aperture ratio. The first initial signal terminal and the second initial signal terminal can output the same or different voltage signals according to actual conditions.

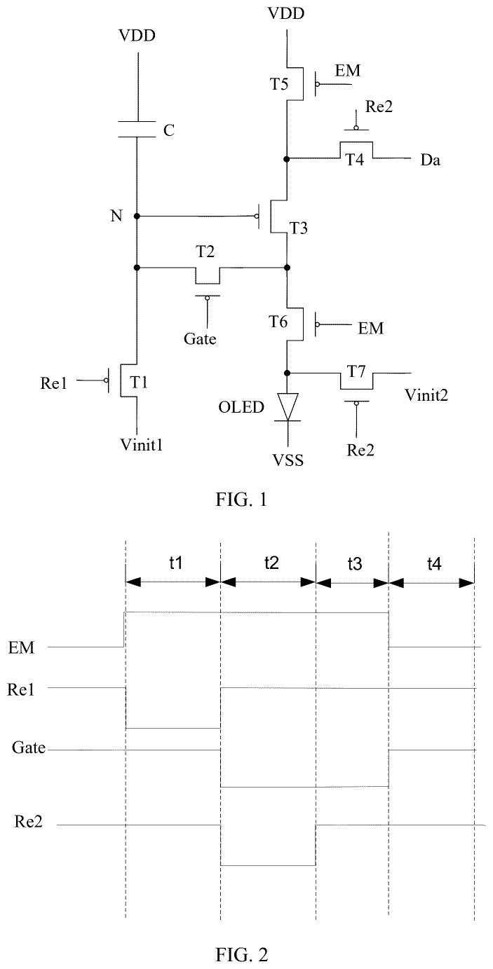

As shown in FIG. 2, it is a timing diagram of the signals on each node in a driving method of the pixel driving circuit shown in FIG. 1. Herein, Gate represents the timing diagram of the signal on the gate driving signal terminal Gate, Re1 represents the timing diagram of the signal on the first reset signal terminal Re1, Re2 represents the timing diagram of the signal on the second reset signal terminal Re2, and EM represents the timing diagram of the signal on the enable signal terminal EM. The driving method of the pixel driving circuit may include a reset stage t1, a first compensation stage t2, a second compensation stage t3, and a light emission stage t4. In the reset stage t1: the first reset signal terminal Re1 outputs a low-level signal, the first transistor T1 is conductive, and the first initial signal terminal Vinit1 inputs the first initial signal to the node N. In the first compensation stage t2: the second reset signal terminal Re2 and the gate driving signal terminal Gate output low-level signals, the fourth transistor T4, the second transistor T2, and the seventh transistor T7 are conductive, and at the same time, the data signal terminal Da outputs a data signal to write a voltage Vdata+Vth to the node N, where Vdata is the voltage of the data signal, and Vth is the threshold voltage of the driving transistor T3; and the second initial signal terminal Vini2 inputs a second initial signal to the second electrode of the sixth transistor T6. In the second compensation stage t3: the gate driving signal terminal Gate outputs a low level, the second transistor T2 is conductive, and the second transistor T2 continues to input a compensation voltage to the node N. In the light emission stage t4: the enable signal terminal EM outputs a low-level signal, the sixth transistor T6 and the fifth transistor T5 are conductive, and the driving transistor T3 drives the light-emitting unit to emit light under the voltage Vdata+Vth at the node N. According to the driving transistor output current formula I=(μWCox/2L)(Vgs−Vth)², where μ is the carrier mobility; Cox is the gate capacitance per unit area, W is the channel width of the driving transistor, L is the channel length of the driving transistor, Vgs is the gate-source voltage difference of the driving transistor, and Vth is the threshold voltage of the driving transistor. The output current of the driving transistor in the pixel driving circuit of the present disclosure is I=(μWCox/2L)(Vdata+Vth−Vdd−Vth)². The pixel driving circuit can extend the time for inputting the compensation voltage to the node N, so that the compensation voltage can be input to the node N more fully.

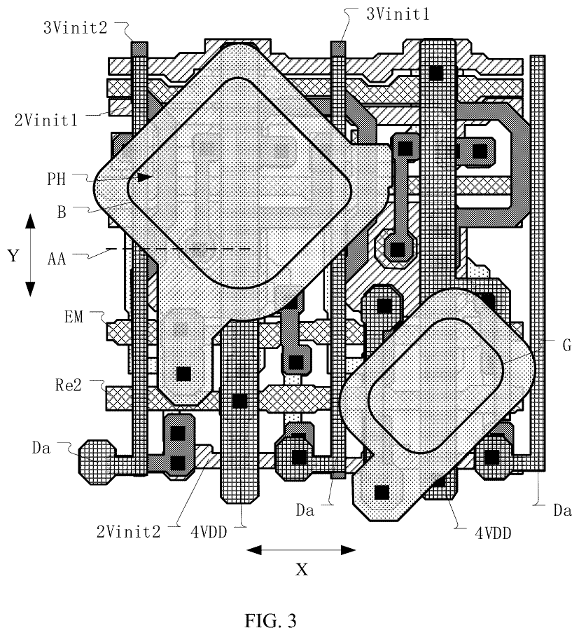

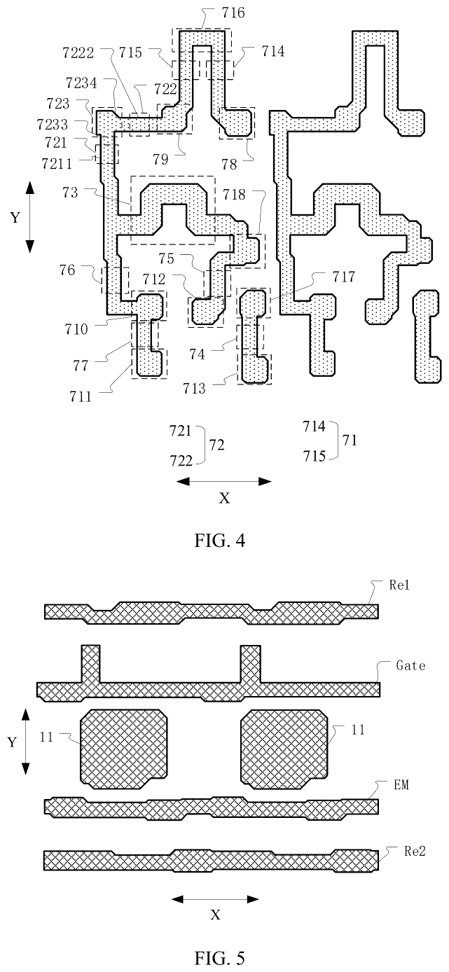

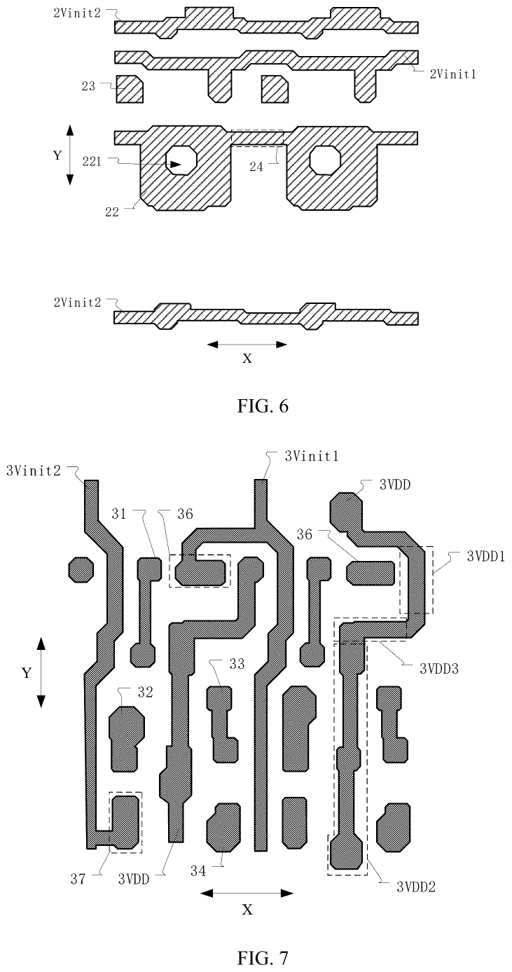

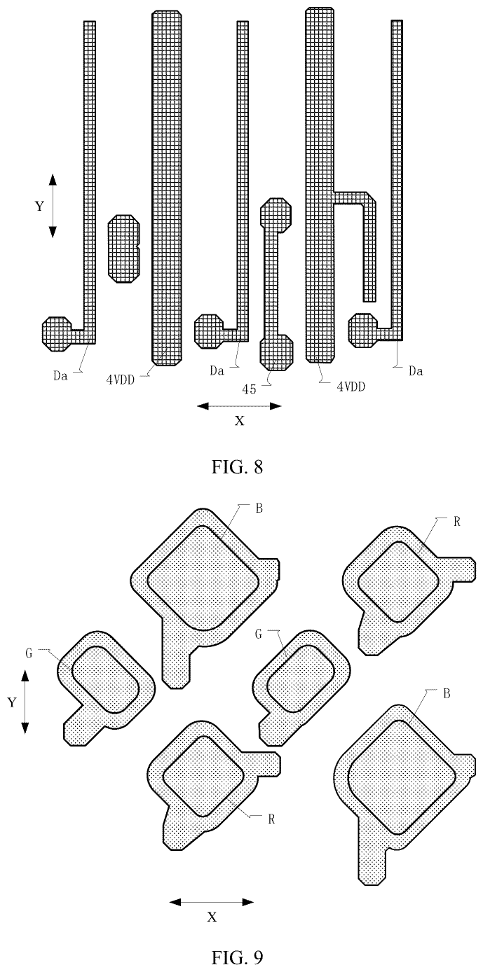

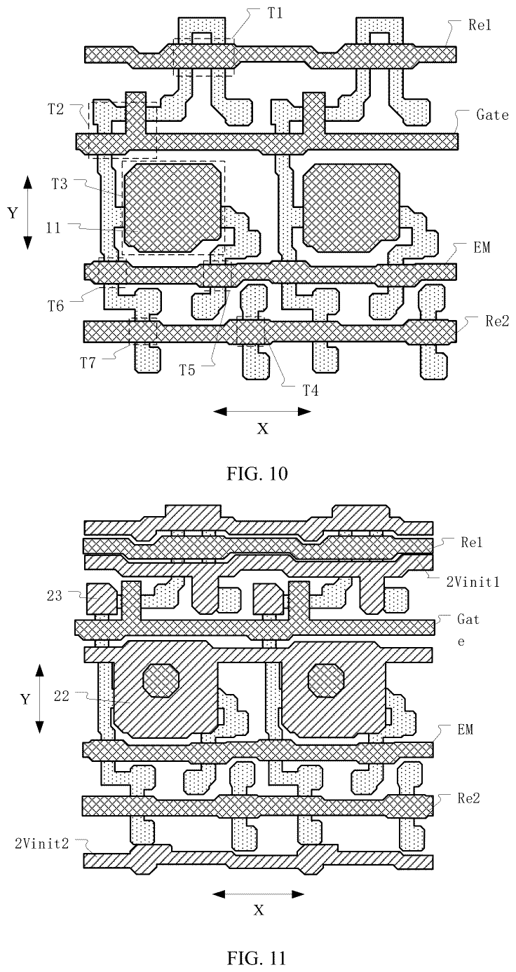

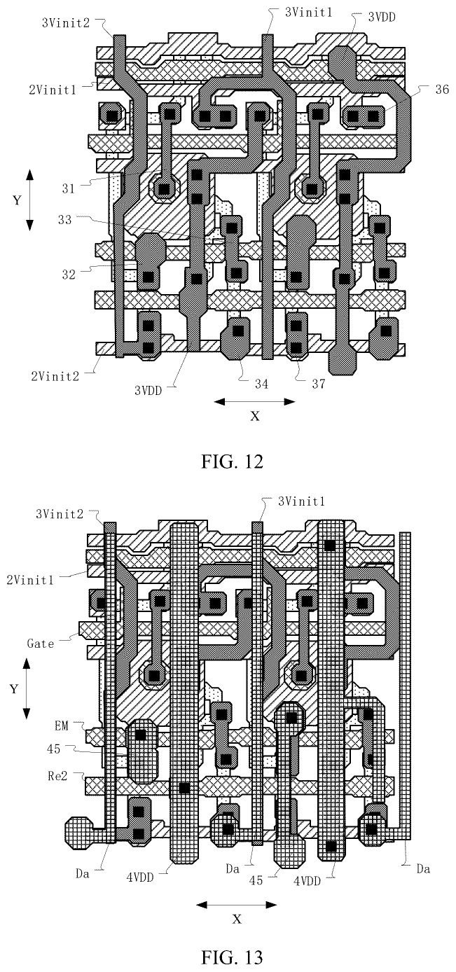

Some exemplary embodiments further provide a display panel, which may include a plurality of pixel driving circuits shown in FIG. 1. In an exemplary embodiment, the display panel may further include a base substrate, an active layer, a first conductive layer, a second conductive layer, a third conductive layer, a fourth conductive layer, and an electrode layer that are staked in sequence, where an insulating layer(s) may be provided between the above structural layers. As shown in FIG. 3 to FIG. 13, FIG. 3 is a structural layout of a display panel according to another exemplary embodiment of this disclosure; FIG. 4 is a structural layout of the active layer in FIG. 3; FIG. 5 is a structural layout of the first conductive layer in FIG. 3; FIG. 6 is a structural layout of the second conductive layer in FIG. 3; FIG. 7 is a structural layout of the third conductive layer in FIG. 3; FIG. 8 is a structural layout of the fourth conductive layer in FIG. 3; FIG. 9 is a structural layout of the electrode layer in FIG. 3; FIG. 10 is a structural layout of the active layer and the first conductive layer in FIG. 3; FIG. 11 is a structural layout of the active layer, the first conductive layer, and the second conductive layer in FIG. 3; FIG. 12 is a structural layout of the active layer, the first conductive layer, the second conductive layer, and the third conductive layer in FIG. 3; and FIG. 13 is a structural layout of the active layer, the first conductive layer, the second conductive layer, the third conductive layer, and the fourth conductive layer in FIG. 3.

As shown in FIG. 3, FIG. 4 and FIG. 10, the active layer may include a first active portion 71, a second active portion 72, a third active portion 73, a fourth active portion 74, a fifth active portion 75, a sixth active portion 76 and a seventh active portion 77. The first active portion 71 is used to form a channel region of the first transistor T1, the second active portion 72 is used to form a channel region of the second transistor T2, the third active portion 73 is used to form a channel region of the driving transistor T3, the fourth active portion 74 is used to form a channel region of the fourth transistor T4, the fifth active portion 75 is used to form a channel region of the fifth transistor T5, the sixth active portion 76 is used to form a channel region of the sixth transistor T6, and the seventh active portion 77 is used to form a channel region of the seventh transistor T7. The first active portion 71 includes a fourth active sub-portion 714 and a fifth active sub-portion 715, and the active layer further includes a sixth active sub-portion connected between the fourth active sub-portion 714 and the fifth active sub-portion 715. The second active portion 72 includes a first active sub-portion 721 and a second active sub-portion 722, and the active layer further includes a third active sub-portion 723 connected between the first active sub-portion 721 and the second active sub-portion 722. As shown in FIG. 3, FIG. 4, and FIG. 10, the active layer may further include an eighth active portion 78, a ninth active portion 79, a tenth active portion 710, an eleventh active portion 711, a twelfth active portion 712, a thirteenth active portion 713, a seventeenth active portion 717, and an eighteenth active portion 718. The eighth active portion 78 is connected to one end of the first active portion 71 away from the second active portion 72, the ninth active portion 79 is connected between the first active portion 71 and the second active portion 72, the tenth active portion 710 is connected between the sixth active portion 76 and the seventh active portion 77, the eleventh active portion 711 is connected to one end of the seventh active portion 77 away from the sixth active portion 76, the twelfth active portion 712 is connected to one end of the fifth active portion 75 away from the third active portion 73, the thirteenth active portion 713 and the seventeenth active portion 717 are connected to two ends of the fourth active portion 74, and the eighteenth active portion 718 is connected between the fifth active portion 75 and the third active portion 73.

In some exemplary embodiments, the active layer portion of each pixel driving circuit is designed independently. This setting is beneficial to improving the vertical mura problem caused by the intra-screen hole (AA Hole).

As shown in FIG. 3, FIG. 5, and FIG. 10, the first conductive layer includes a first conductive portion 11, a gate line Gate, a first reset signal line Re1, a second reset signal line Re2, and an enable signal line EM. The orthographic projections of the gate line Gate, the first reset signal line Re1, the second reset signal line Re2, and the enable signal line EM on the base substrate extend along the first direction X. The gate line Gate is used to provide the gate driving signal terminal in FIG. 1, the first reset signal line Re1 is used to provide the first reset signal terminal in FIG. 1, the second reset signal line Re2 is used to provide the second reset signal terminal in FIG. 1, and the enable signal line EM is used to provide the enable signal terminal in FIG. 1. The orthographic projection of the gate line Gate on the base substrate covers the orthographic projection of the second active portion 72 on the base substrate, and a partial structure of the gate line Gate is used to form the gate of the second transistor T2. The orthographic projection of the first reset signal line Re1 on the base substrate covers the orthographic projection of the first active portion 71 on the base substrate, and a partial structure of the first reset signal line Re1 is used to form the gate of the first transistor T1. The orthographic projection of the second reset signal line Re2 on the base substrate covers the orthographic projections of the fourth active portion 74 and the seventh active portion 77 on the base substrate, and a partial structure of the second reset signal line Re2 is used to form the gates of the fourth transistor T4 and the seventh transistor T7, respectively. The orthographic projection of the enable signal line EM on the base substrate covers the orthographic projections of the fifth active portion 75 and the sixth active portion 76 on the base substrate, and a partial structure of the enable signal line EM is used to form the gates of the fifth transistor T5 and T6, respectively. The orthographic projection of the first conductive portion 11 on the base substrate covers the orthographic projection of the third active portion 73 on the base substrate, and the first conductive portion 11 is used to form the gate of the driving transistor T3 and the first electrode of the capacitor C.

In some exemplary embodiments, the second transistor T2 and the fourth transistor T4 can be provided with gate driving signals by different gate driving circuits, and the fourth transistor T4 and the seventh transistor T7 can be provided with gate driving signals by the same gate driving circuit. As shown in FIG. 3, FIG. 5, and FIG. 10, adjacent rows of pixel driving circuits do not share gate lines, and this setting can facilitate the insertion of analog pixel driving circuit rows in the display panel.

As shown in FIG. 3, FIG. 6 and FIG. 11, the second conductive layer may include a first initial signal line 2Vinit1, a second initial signal line 2Vinit2, a second conductive portion 22 and a third conductive portion 23. The first initial signal line 2Vinit1 may be used to provide the first initial signal terminal in FIG. 1, and the second initial signal line 2 Vinit2 may be used to provide the second initial signal terminal in FIG. 1. The orthographic projection of the first initial signal line 2Vinit1 on the base substrate and the orthographic projection of the second initial signal line 2Vinit2 on the base substrate may extend along the first direction X. The orthographic projection of the second conductive portion 22 on the base substrate may at least partially overlap with the orthographic projection of the first conductive portion 11 on the base substrate, and the second conductive portion 22 may be used to form a second electrode of the capacitor C, where a plurality of second conductive portions 22 distributed in the first direction X may be connected in sequence. The orthographic projection of the third conductive portion 23 on the base substrate and the orthographic projection of the third active sub-portion 723 on the base substrate at least partially overlap, and the third conductive portion 23 may be connected to a stable voltage source, where the third conductive portion 23 may stabilize the third active sub-portion 723, thereby improving the problem of leakage to the source and drain of the second transistor T2 due to the voltage change of the third active sub-portion 723.

As shown in FIG. 3, FIG. 4 and FIG. 10, the first active sub-portion 721 as a channel region includes a first side 7211 extending along the length direction of the channel region, the second active sub-portion 722 as a channel region includes a second side 7222 extending along the length direction of the channel region, and the third active sub-portion 723 includes a third side 7233 and a fourth side 7234. The third side 7233 is connected to the first side 7211, and the angle formed by the third side 7233 and the first side 7211 is less than 180°. The fourth side 7234 is connected to the second side 7222, and the angle formed by the fourth side 7234 and the second side 7222 is less than 180°. In other words, the third active sub-portion 723 is enlarged, thereby increasing the overlapping area between the orthographic projections of the third active sub-portion 723 and the third conductive portion 23 on the base substrate, and improving the voltage stabilizing effect of the third conductive portion 23 on the third active sub-portion 723.

As shown in FIG. 3, FIG. 6, and FIG. 11, the orthographic projection, on the base substrate, of the second initial signal line 2Vinit2 corresponding to the pixel driving circuit in the adjacent previous row can at least partially overlap with the orthographic projection of the sixth active sub-portion 716 on the base substrate, and the second initial signal line 2Vinit2 corresponding to the pixel driving circuit in the adjacent previous row on the base substrate can stabilize the sixth active sub-portion 716, thereby improving the problem of leakage to the source and drain of the first transistor T1 caused by the voltage change of the sixth active sub-portion 716.

As shown in FIG. 3, FIG. 6, and FIG. 11, the pixel driving circuit shown in FIG. 3 is the pixel driving circuit of the bottom row of the display panel, and the second initial signal line 2Vinit2 corresponding to this pixel driving circuit does not need to block the sixth active sub-portion in the pixel driving circuit of the next row. Therefore, the second initial signal line 2Vinit2 corresponding to this pixel driving circuit and the second initial signal line 2Vinit2 corresponding to the adjacent previous row of pixel driving circuit have slightly different structures. Alternatively, in other exemplary embodiments, the second initial signal line 2Vinit2 corresponding to the pixel driving circuit of the bottom row of the display panel can also have the same structure as other second initial signal lines 2Vinit2.

As shown in FIG. 3, FIG. 7, and FIG. 12, the third conductive layer may include a power line 3VDD, a first initial connection line 3Vinit1, a second initial connection line 3Vinit2, a first bridge portion 31, a second bridge portion 32, a third bridge portion 33, a fourth bridge portion 34, a sixth bridge portion 36, and a seventh bridge portion 37. Herein, the power line 3VDD can be used to provide the first power terminal in the pixel driving circuit shown in FIG. 1. The orthographic projections of the power line 3VDD, the first initial connection line 3Vinit1, and the second initial connection line 3Vinit2 on the base substrate may extend along the second direction Y. The first direction X may intersect with the second direction Y, for example, the first direction X may be a row direction, and the second direction Y may be a column direction. One column of pixel driving circuits distributed in the second direction Y may be provided with one corresponding first initial connection line 3Vinit1 or one corresponding second initial connection line 3Vinit2. The orthographic projections of the first initial connection line 3Vinit1 and the second initial connection line 3Vinit2 on the base substrate may be distributed alternately in sequence along the first direction X. The power line 3VDD may be connected to the second conductive portion 22 and the twelfth active portion 712 through vias, respectively, so as to connect the second electrode of the capacitor C, the first electrode of the fifth transistor T5 and the first power terminal.

As shown in FIG. 3, FIG. 7, and FIG. 12, the power line 3VDD can also be connected to the third conductive portion 23 through a via, and the power line 3VDD can provide a stable voltage source to the third conductive portion 23. It should be understood that in other exemplary embodiments, the third conductive portion 23 can also be connected to the power line by being connected to the second conductive portion 22 in the same layer. The third conductive portion 23 can also provide a stable voltage source through other structures. For example, the third conductive portion 23 can provide a stable voltage source through structures such as the first initial signal line 2Vinit1 and the second initial signal line 2Vinit2. The first bridge portion 31 can be connected to the first conductive portion 11 and the ninth active part 79 through vias, respectively, so as to connect the second electrode of the first transistor T1, the first electrode of the second transistor, and the gate of the driving transistor T3. Herein, an opening 221 is formed on the second conductive portion 22, and the orthographic projection of the via connected between the first conductive portion 11 and the first bridge portion 31 on the base substrate is located within the orthographic projection of the opening 221 on the base substrate. The second bridge portion 32 can be connected to the tenth active part 710 through a via to connect the second electrode of the sixth transistor T6. The third bridge portion 33 may be connected to the seventeenth active portion 717 and the eighteenth active portion 718 through vias, respectively, to connect the second electrode of the fourth transistor T4 and the first electrode of the driving transistor T3. The fourth bridge portion 34 may be connected to the thirteenth active portion 713 through vias to connect the first electrode of the fourth transistor T4. The sixth bridge portion 36 may be connected to the first initial signal line 2Vinit1 and the eighth active portion 78 through vias, respectively, to connect the first electrode of the first transistor T1 and the first initial signal terminal. The seventh bridge portion 37 may be connected to the second initial signal line 2Vinit2 and the eleventh active portion 711 through vias, respectively, to connect the first electrode of the seventh transistor T7 and the second initial signal terminal. The first initial connection line 3Vinit1 may be connected, through the sixth bridge portion 36, to the first initial signal line 2Vinit1 having their orthographic projections on the base substrate intersecting with each other, so as to form a grid structure with the first initial signal line 2Vinit1. This setting can reduce the self-resistance of the first initial signal line 2Vinit1, thereby improving the voltage uniformity of the first initial signal terminal connected to the pixel driving circuits at different positions of the display panel. The second initial connection line 3Vinit2 can be connected, through the seventh bridge portion 37, to the second initial signal line 2Vinit2 having their orthographic projections on the base substrate intersecting with each other, so as to form a grid structure with the second initial signal line 2Vinit2. This setting can reduce the self-resistance of the second initial signal line 2Vinit2, thereby improving the voltage uniformity of the second initial signal terminal connected to the pixel driving circuits at different positions of the display panel. It should be understood that in other exemplary embodiments, the first initial connection line 3Vinit1 and the second initial connection line 3Vinit2 can also have other distribution manners. As long as the first initial connection line 3Vinit 1 and the first initial signal line 2Vinit1 form a grid structure, and the second initial connection line 3Vinit2 and the second initial signal line 2Vinit2 form a grid structure, the above-mentioned technical effect can be achieved.

As shown in FIG. 3, FIG. 6, FIG. 7 and FIG. 12, the power line 3VDD may include: a first extension portion 3VDD1, a second extension portion 3VDD2, and a third extension portion 3VDD3, where the third extension portion 3VDD3 is connected between the first extension portion 3VDD1 and the second extension portion 3VDD2. The orthographic projection of the first extension portion 3VDD1 on the base substrate and the orthographic projection of the second extension portion 3VDD2 on the base substrate extend along the second direction Y, and the orthographic projection of the third extension portion 3VDD3 on the base substrate extends along the first direction. The second conductive layer also includes a fourth conductive portion 24 connected between adjacent second conductive portions 22 in the first direction X. The orthographic projection of the third extension portion 3VDD3 on the base substrate and the orthographic projection of the fourth conductive portion 24 on the base substrate at least partially overlap. This arrangement can improve the transmittance of the display panel.

As shown in FIG. 3, FIG. 8, and FIG. 13, the fourth conductive layer may include: a data line Da, a power connection line 4VDD, and a fifth bridge portion 45. The orthographic projections of the data line Da and the power connection line 4VDD on the base substrate extend along the second direction Y. The data line Da is used to provide the data signal terminal in FIG. 1. The data line Da can be connected to the fourth bridge portion 34 through a via, so as to connect the first electrode of the fourth transistor T4. The power connection line 4VDD can be connected to the power line 3VDD through a via to form a double-layer power line. This setting can reduce the self-resistance of the power line, thereby improving the voltage uniformity of the first power supply terminal at different positions of the display panel. The fifth bridge portion 45 can be connected to the second bridge portion 32 through a via to connect the second electrode of the sixth transistor T6.

As shown in FIG. 3, FIG. 8 and FIG. 13, the orthographic projection of part of the data line Da on the base substrate at least partially overlaps with the orthographic projection of the first initial connection line 3Vinit1 on the base substrate; and the orthographic projection of part of the data line Da on the base substrate at least partially overlaps with the orthographic projection of the second initial connection line 3Vinit2 on the base substrate. This setting can improve the transmittance of the display panel.

In some exemplary embodiments, in the data line Da and the first initial connection line 3Vinit1 with their orthographic projections on the base substrate intersecting, the overlapping area between the orthographic projection of the data line Da on the base substrate and the orthographic projection of the first initial connection line 3Vinit1 on the base substrate is S1, the area of the orthographic projection of the data line Da on the base substrate is S2, and S1/S2 is greater than or equal to 50%. For example, S1/S2 can be equal to 50%, 60%, 70%, 80%, 90%, or the like. In the data line Da and the second initial connection line 3Vinit2 with their orthographic projections on the base substrate intersecting, the overlapping area between the orthographic projection of the data line Da on the base substrate and the orthographic projection of the second initial connection line 3Vinit2 on the base substrate is S3, the area of the orthographic projection of the data line Da on the base substrate is S4, and S3/S4 is greater than or equal to 50%, for example, S 3/S4 can be equal to 50%, 60%, 70%, 80%, 90%, or the like.

As shown in FIG. 3 and FIG. 9, the electrode layer includes multiple electrode portions: a first electrode portion G, a second electrode portion B, and a third electrode portion R. Each electrode portion can be connected to the fifth bridge part 45 through a via to connect the second electrode of the sixth transistor. In particular, FIG. 9 shows more electrode portions corresponding to the pixel driving circuit compared to FIG. 3. The display panel may also include a pixel definition layer located on the side of the electrode layer away from the base substrate, and a plurality of pixel openings PH are formed on the pixel definition layer. The pixel openings PH are arranged corresponding to the electrode portions, and the orthographic projection of the pixel openings PH on the base substrate coincides with the orthographic projection of the electrode portions on the base substrate. The first electrode portion G can be used to form the electrode portion of the green light-emitting unit in the display panel, the second electrode portion B can be used to form the electrode portion of the blue light-emitting unit in the display panel, and the third electrode portion R can be used to form the electrode portion of the red light-emitting unit. Among the multiple electrode portions connected to the same row of pixel driving circuits, the second electrode portion B, the first electrode portion G, the third electrode portion R, and the first electrode portion G are alternately distributed in sequence in the row direction X. In two adjacent columns of pixel driving circuits, the multiple second electrode portions B and the multiple third electrode portions R are connected to the same column of pixel driving circuits, and the second electrode portions B and the third electrode portions R connected to the same column of pixel driving circuits are alternately distributed in sequence in the column direction Y; the multiple first electrode portions G are connected to another column of pixel driving circuits, and the first electrode portions G connected to the same column of pixel driving circuits are spaced apart in the column direction.

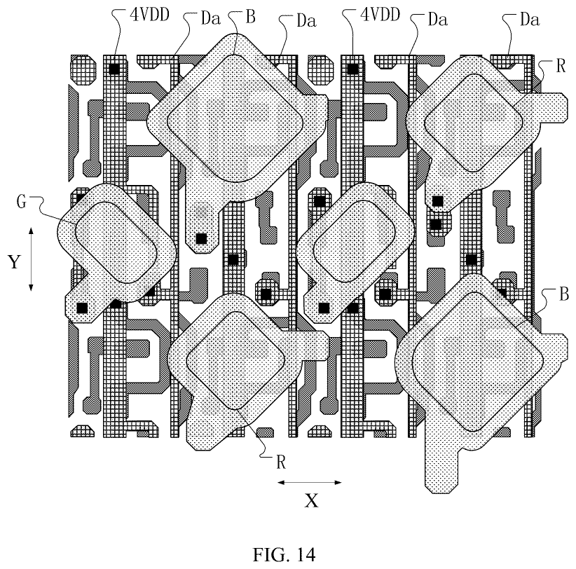

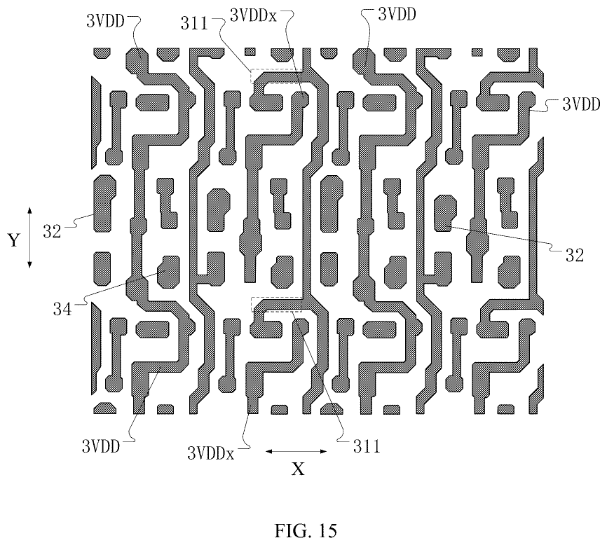

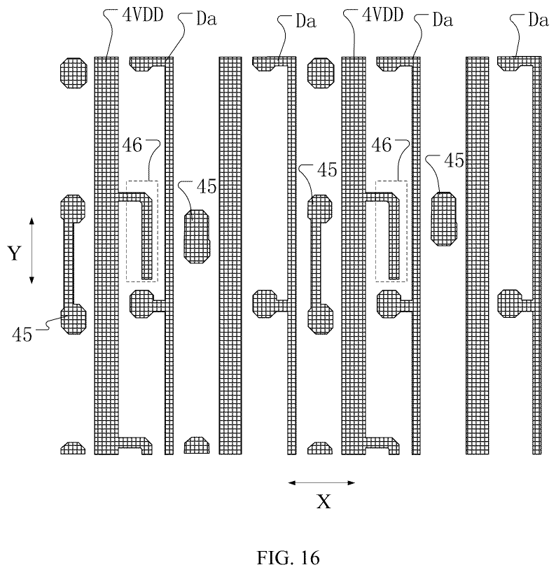

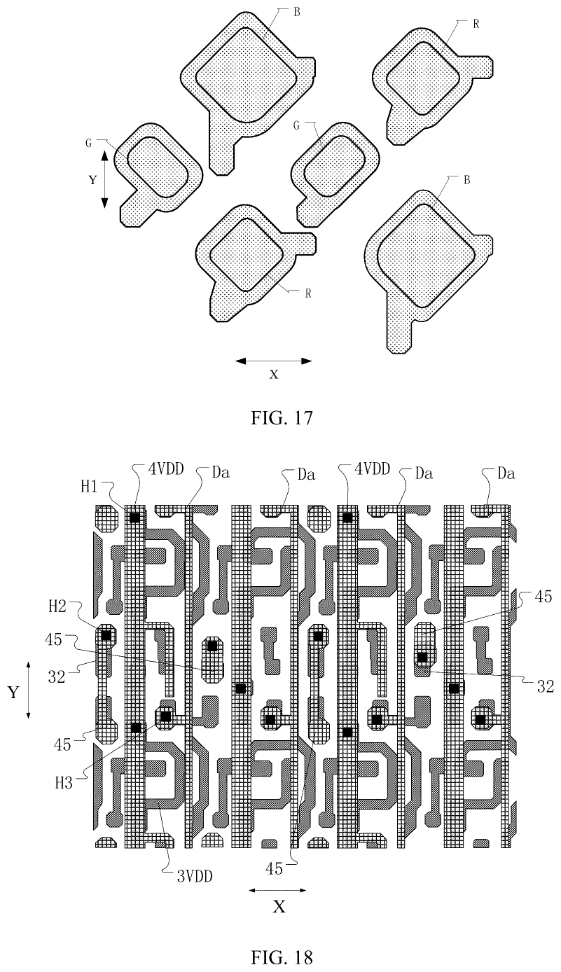

As shown in FIG. 14 to FIG. 18, FIG. 14 is a structural layout of a display panel according to an exemplary embodiment of this disclosure. The display panel shown in FIG. 14 has the same structure as the display panel shown in FIG. 3, and FIG. 14 only shows the third conductive layer, the fourth conductive layer, and the electrode layer in the display panel. FIG. 15 is a structural layout of the third conductive layer in FIG. 14; FIG. 16 is a structural layout of the fourth conductive layer in FIG. 14; FIG. 17 is a structural diagram of the electrode layer in FIG. 14; and FIG. 18 is a structural layout of the third conductive layer and the fourth conductive layer in FIG. 14.

As shown in FIG. 14 to FIG. 18, a partial structure of the fourth conductive layer is connected to a partial structure of the third conductive layer through a via. For example, the power connection line 4VDD is connected to the power line 3VDD through the first via H1, the fifth bridge portion 45 is connected to the second bridge portion 32 through the second via H2, and the data line Da is connected to the fourth bridge portion 34 through the third via H3. The orthographic projection of the via connected between the fourth conductive layer and the third conductive layer on the base substrate and the orthographic projection of each electrode portion on the base substrate do not overlap. Since the fourth conductive layer is provided with grooves at the positions corresponding to the first via H1, the second via H2, the third via H3 and other vias, the above setting can avoid the electrode portion(s) from being formed on the groove, thereby improving the flatness of the electrode portion. As shown in FIG. 14 to FIG. 18, in different pixel driving circuits, the position of the first via H1 can be set differently, so that the orthographic projection of the first via H1 on the base substrate and the orthographic projection of each electrode portion on the base substrate do not overlap.

As shown in FIG. 14 to FIG. 18, the fifth bridge portion 45 raises the left side of the first electrode portion G, thereby affecting the flatness of the first electrode portion G. In some exemplary embodiments, the fourth conductive layer may further include a sixth conductive portion 46, and the orthographic projection of the first electrode portion G on the base substrate overlaps with the orthographic projections of the sixth conductive portion 46 and the fifth bridge portion 45 on the base substrate. The orthographic projection of the sixth conductive portion 46 on the base substrate is arranged close to a side of the orthographic projection of the first electrode portion G on the base substrate in the first direction X, and the orthographic projection of the fifth bridge portion 45 on the base substrate is arranged close to the other side of the orthographic projection of the first electrode portion G on the base substrate in the first direction X. The sixth conductive portion 46 and the fifth bridge portion 45 overlap with the left and right sides of the first electrode portion G, respectively, so that the symmetry of the left and right sides of the first electrode portion G can be improved, thereby improving the flatness of the first electrode portion G.

As shown in FIG. 14 to FIG. 18, in the same pixel driving circuit, the sixth conductive portion 46 is connected to the side of the power connection line 4VDD away from the fifth bridge portion 45. The sixth conductive portion 46 has a stable voltage, so that it will not produce voltage coupling effects on other structures. It should be understood that in other exemplary embodiments, the sixth conductive portion 46 can be suspended or connected to another stable voltage source.

In some exemplary embodiments, the electrode portion overlapping with the fifth bridge portion 45 and the sixth conductive portion 46 is the first electrode portion G. It should be understood that in other exemplary embodiments, the electrode portion overlapping with the fifth bridge portion 45 and the sixth conductive portion 46 may also be other electrode portions, for example, the second electrode portion B, the third electrode portion R, and the like.

As shown in FIG. 14 to FIG. 18, the third conductive layer further includes: a first connection portion 311, where the orthographic projection of the first connection portion 311 on the base substrate extends along the first direction X, and the first connection portion 311 is connected between the first initial connection line 3Vinit1 and the pixel driving circuit. As shown in FIG. 14 to FIG. 18, due to the obstruction of the first connection portion 311, part of the power line 3VDD cannot be set through in the second direction Y, and part of the power line 3VDD includes a plurality of power line segments 3VDDx spaced apart in the second direction Y, where the orthographic projection of the first connection portion 311 on the base substrate is located between the orthographic projections, on the base substrate, of adjacent power line segments 3VDDx in the same power line.

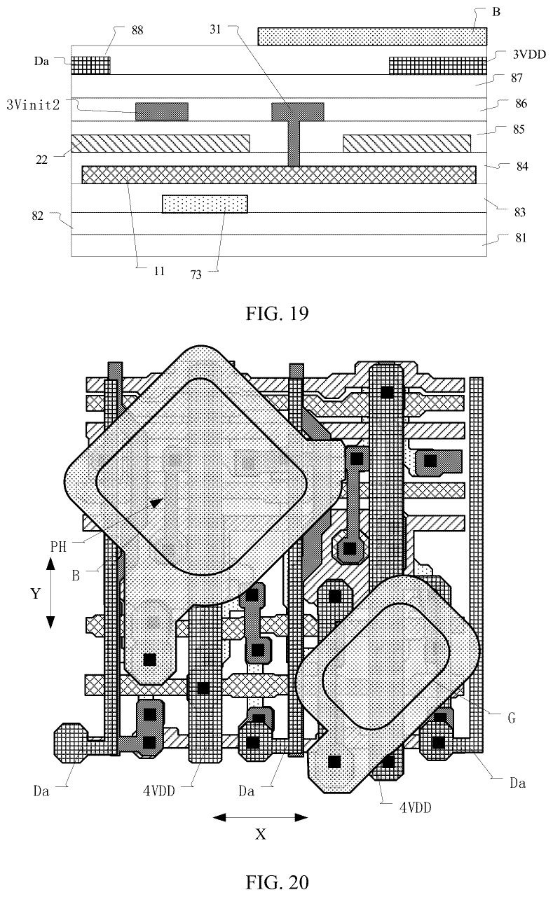

As shown in FIG. 19, it is a partial cross-sectional view of the display panel shown in FIG. 3 taken along the dotted line AA. The display panel may further include a buffer layer 82, a first insulating layer 83, a second insulating layer 84, a first dielectric layer 85, a passivation layer 86, a first planarization layer 87, and a second planarization layer 88, where the base substrate 81, the buffer layer 82, the active layer, the first insulating layer 83, the first conductive layer, the second insulating layer 84, the second conductive layer, the first dielectric layer 85, the third conductive layer, the passivation layer 86, the first planarization layer 87, the fourth conductive layer, the second planarization layer 88, and the electrode layer are stacked in sequence. The first insulating layer 83 and the second insulating layer 84 may be silicon oxide layers; the first dielectric layer 85 may be a silicon nitride layer; the passivation layer 86 and the buffer layer 82 may be made of silicon oxide, silicon nitride, or the like; and the first planarization layer 87 and the second planarization layer 88 may be made of organic materials, such as polyimide (PI), polyethylene terephthalate (PET), polyethylene naphthalate (PEN), silicon-glass bonding structure (SOG), or the like. The base substrate 81 may include a glass substrate, a barrier layer, and a polyimide layer stacked in sequence, where the barrier layer may be an inorganic material. The materials of the first conductive layer and the second conductive layer may be one of molybdenum, aluminum, copper, titanium, and niobium, or an alloy thereof; or a molybdenum/titanium alloy or laminate, or the like. The materials of the third conductive layer and the fourth conductive layer may include metal materials, such as one of molybdenum, aluminum, copper, titanium, and niobium, or an alloy thereof; or a molybdenum/titanium alloy or laminate; or may be a titanium/aluminum/titanium laminate. The square resistance of any one of the first conductive layer and the second conductive layer may be greater than the square resistance of any one of the third conductive layer and the fourth conductive layer.

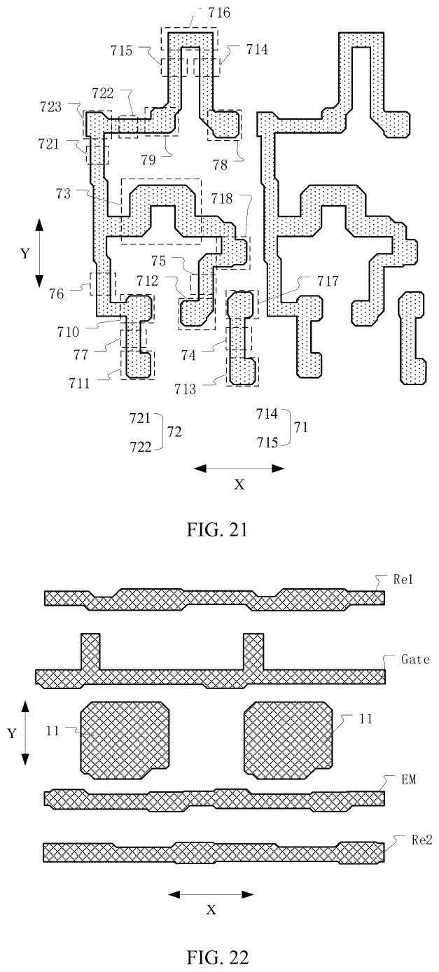

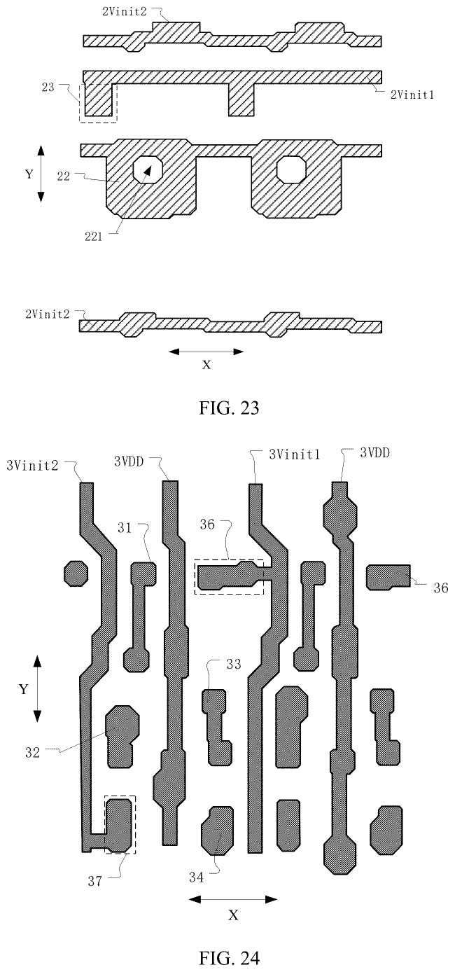

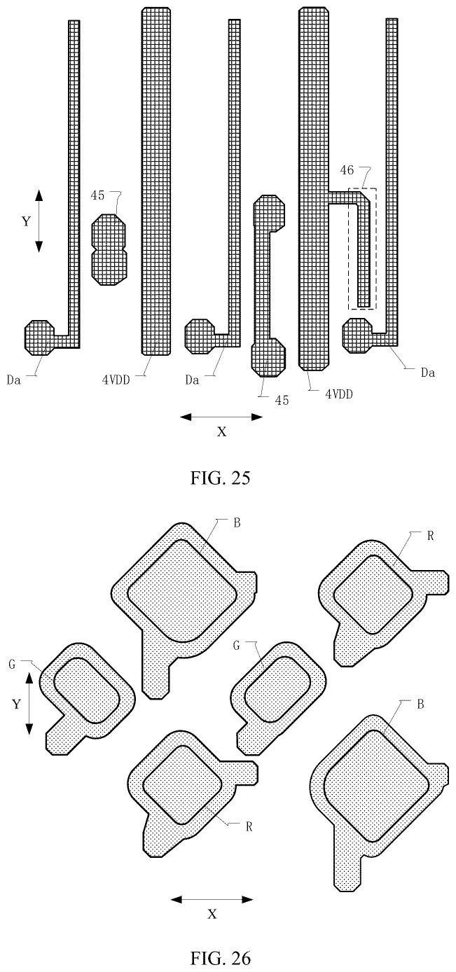

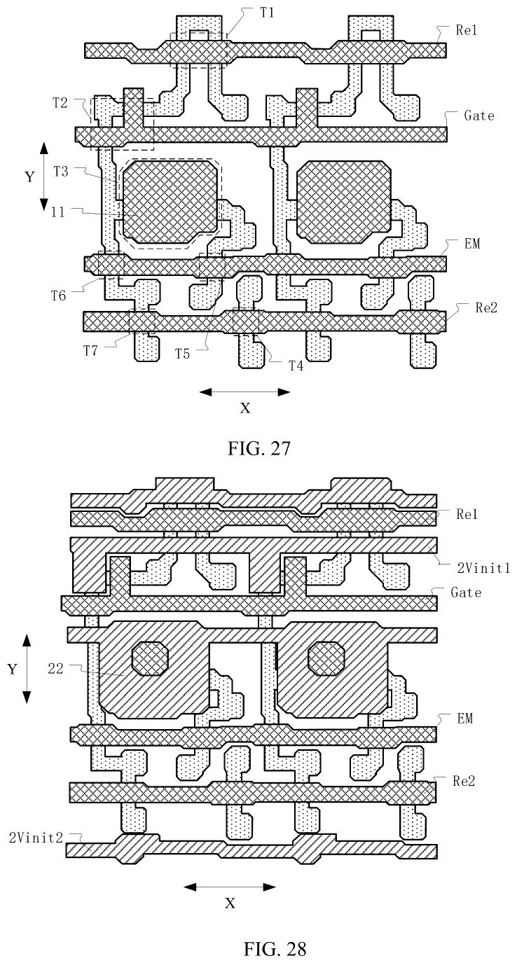

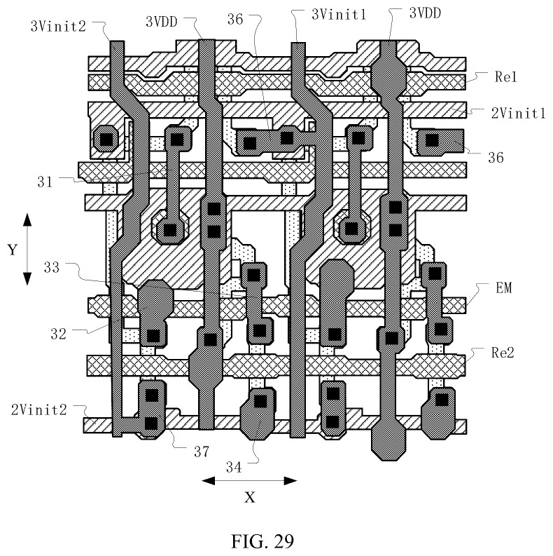

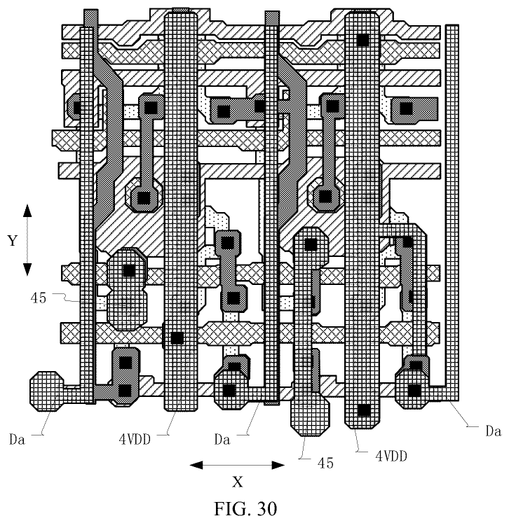

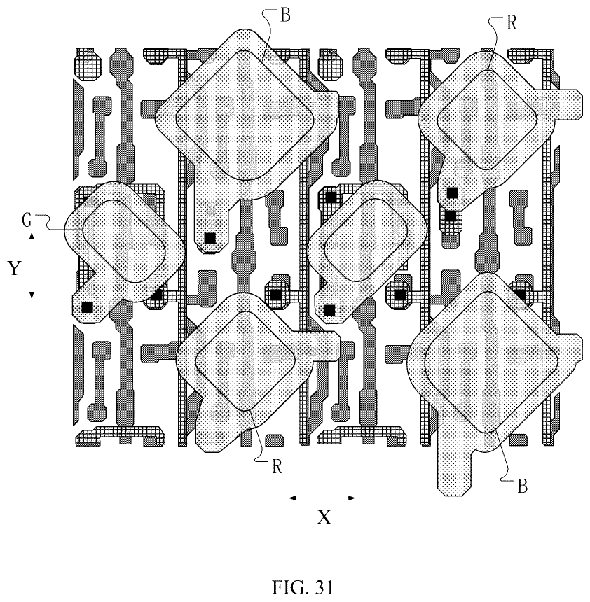

Some exemplary embodiments also provide another display panel, which may include a plurality of pixel driving circuits shown in FIG. 1. In some exemplary embodiments, the display panel may also include a base substrate, an active layer, a first conductive layer, a second conductive layer, a third conductive layer, a fourth conductive layer, and an electrode layer stacked in sequence, and an insulating layer(s) may be provided between the above structural layers. As shown in FIG. 20 to FIG. 30, FIG. 20 is a structural layout of a display panel according to another exemplary embodiment of this disclosure; FIG. 21 is a structural layout of the active layer in FIG. 20; FIG. 22 is a structural layout of the first conductive layer in FIG. 20; FIG. 23 is a structural layout of the second conductive layer in FIG. 20; FIG. 24 is a structural layout of the third conductive layer in FIG. 20; FIG. 25 is a structural layout of the fourth conductive layer in FIG. 20; FIG. 26 is a structural layout of the electrode layer in FIG. 20; FIG. 27 is a structural layout of the active layer and the first conductive layer in FIG. 20; FIG. 28 is a structural layout of the active layer, the first conductive layer, and the second conductive layer in FIG. 20; FIG. 29 is a structural layout of the active layer, the first conductive layer, the second conductive layer, and the third conductive layer in FIG. 20; and FIG. 30 is a structural layout of the active layer, the first conductive layer, the second conductive layer, the third conductive layer, and the fourth conductive layer in FIG. 20.

As shown in FIG. 20, FIG. 21 and FIG. 27, the active layer may include a first active portion 71, a second active portion 72, a third active portion 73, a fourth active portion 74, a fifth active portion 75, a sixth active portion 76 and a seventh active portion 77. The first active portion 71 is used to form a channel region of the first transistor T1, the second active portion 72 is used to form a channel region of the second transistor T2, the third active portion 73 is used to form a channel region of the driving transistor T3, the fourth active portion 74 is used to form a channel region of the fourth transistor T4, the fifth active portion 75 is used to form a channel region of the fifth transistor T5, the sixth active portion 76 is used to form a channel region of the sixth transistor T6, and the seventh active portion 77 is used to form a channel region of the seventh transistor T7. The first active portion 71 includes a fourth active sub-portion 714 and a fifth active sub-portion 715, and the active layer further includes a sixth active sub-portion connected between the fourth active sub-portion 714 and the fifth active sub-portion 715. The second active portion 72 includes a first active sub-portion 721 and a second active sub-portion 722, and the active layer further includes a third active sub-portion 723 connected between the first active sub-portion 721 and the second active sub-portion 722. As shown in FIG. 3, FIG. 4, and FIG. 10, the active layer may further include an eighth active portion 78, a ninth active portion 79, a tenth active portion 710, an eleventh active portion 711, a twelfth active portion 712, a thirteenth active portion 713, a seventeenth active portion 717, and an eighteenth active portion 718. The eighth active portion 78 is connected to one end of the first active portion 71 away from the second active portion 72; the ninth active portion 79 is connected between the first active portion 71 and the second active portion 72; the tenth active portion 710 is connected between the sixth active portion 76 and the seventh active portion 77; the eleventh active portion 711 is connected to one end of the seventh active portion 77 away from the sixth active portion 76; the twelfth active portion 712 is connected to one end of the fifth active portion 75 away from the third active portion 73; the thirteenth active portion 713 and the seventeenth active portion 717 are connected to two ends of the fourth active portion 74; and the eighteenth active portion 718 is connected between the fifth active portion 75 and the third active portion 73.

As shown in FIG. 20, FIG. 22, and FIG. 27, the first conductive layer includes a first conductive portion 11, a gate line Gate, a first reset signal line Re1, a second reset signal line Re2, and an enable signal line EM. The orthographic projections of the gate line Gate, the first reset signal line Re1, the second reset signal line Re2, and the enable signal line EM on the base substrate extend along the first direction X. The gate line Gate is used to provide the gate driving signal terminal in FIG. 1, the first reset signal line Re1 is used to provide the first reset signal terminal in FIG. 1, the second reset signal line Re2 is used to provide the second reset signal terminal in FIG. 1, and the enable signal line EM is used to provide the enable signal terminal in FIG. 1. The orthographic projection of the gate line Gate on the base substrate covers the orthographic projection of the second active portion 72 on the base substrate, and a partial structure of the gate line Gate is used to form the gate of the second transistor T2. The orthographic projection of the first reset signal line Re1 on the base substrate covers the orthographic projection of the first active portion 71 on the base substrate, and a partial structure of the first reset signal line Re1 is used to form the gate of the first transistor T1. The orthographic projection of the second reset signal line Re2 on the base substrate covers the orthographic projections of the fourth active portion 74 and the seventh active portion 77 on the base substrate, and a partial structure of the second reset signal line Re2 is used to form the gates of the fourth transistor T4 and the seventh transistor T7, respectively. The orthographic projection of the enable signal line EM on the base substrate covers the orthographic projections of the fifth active portion 75 and the sixth active portion 76 on the base substrate, and a partial structure of the enable signal line EM is used to form the gates of the fifth transistor T5 and T6, respectively. The orthographic projection of the first conductive portion 11 on the base substrate covers the orthographic projection of the third active portion 73 on the base substrate, and the first conductive portion 11 is used to form the gate of the driving transistor T3 and the first electrode of the capacitor C.

As shown in FIG. 20, FIG. 23, and FIG. 28, the second conductive layer may include a first initial signal line 2Vinit1, a second initial signal line 2Vinit2, a second conductive portion 22, and a third conductive portion 23. The first initial signal line 2Vinit1 may be used to provide the first initial signal terminal in FIG. 1, and the second initial signal line 2Vinit2 may be used to provide the second initial signal terminal in FIG. 1. The orthographic projection of the first initial signal line 2Vinit1 on the base substrate and the orthographic projection of the second initial signal line 2Vinit2 on the base substrate may both extend along the first direction X. The orthographic projection of the second conductive portion 22 on the base substrate may at least partially overlap with the orthographic projection of the first conductive portion 11 on the base substrate, and the second conductive portion 22 may be used to form a second electrode of the capacitor C, and a plurality of second conductive portions distributed in the first direction X may be connected in sequence. The orthographic projection of the third conductive portion 23 on the base substrate and the orthographic projection of the third active sub-portion 723 on the base substrate at least partially overlap. The third conductive portion 23 can be connected to the first initial signal line 2Vinit1, and the third conductive portion 23 can stabilize the voltage of the third active sub-portion 723, thereby improving the problem of leakage to the source and drain of the second transistor T2 due to the voltage change of the third active sub-portion 723.

As shown in FIG. 20, FIG. 21 and FIG. 27, the third active sub-portion 723 is enlarged, thereby increasing the overlapping area between the orthographic projections of the third active sub-portion 723 and the third conductive portion 23 on the base substrate, and improving the voltage stabilizing effect of the third conductive portion 23 on the third active sub-portion 723.

As shown in FIG. 20, FIG. 23, and FIG. 28, the orthographic projection, on the base substrate, of the second initial signal line 2Vinit2 corresponding to the pixel driving circuit in the adjacent previous row can at least partially overlap with the orthographic projection of the sixth active sub-portion 716 on the base substrate, and the second initial signal line 2Vinit2 corresponding to the pixel driving circuit in the adjacent previous row can stabilize the sixth active sub-portion 716, thereby improving the problem of leakage to the source and drain of the first transistor T1 caused by the voltage change of the sixth active sub-portion 716.

As shown in FIG. 20, FIG. 23, and FIG. 28, the pixel driving circuit shown in FIG. 20 is the pixel driving circuit of the bottom row of the display panel. The second initial signal line 2Vinit2 corresponding to this pixel driving circuit does not need to block the sixth active sub-portion in the pixel driving circuit of the next row. Therefore, the second initial signal line 2Vinit2 corresponding to this pixel driving circuit and the second initial signal line 2Vinit2 corresponding to the adjacent previous row of pixel driving circuits have slightly different structures. Alternatively, in other exemplary embodiments, the second initial signal line 2Vinit2 corresponding to the pixel driving circuit of the bottom row of the display panel can also have the same structure as other second initial signal lines 2Vinit2.

As shown in FIG. 20, FIG. 24, and FIG. 29, the third conductive layer may include a power line 3VDD, a first initial connection line 3Vinit1, a second initial connection line 3Vinit2, a first bridge portion 31, a second bridge portion 32, a third bridge portion 33, a fourth bridge portion 34, a sixth bridge portion 36, and a seventh bridge portion 37. Herein, the power line 3VDD can be used to provide the first power terminal in the pixel driving circuit shown in FIG. 1. The orthographic projections of the power line 3VDD, the first initial connection line 3Vinit1, and the second initial connection line 3Vinit2 on the base substrate can extend along the second direction Y. One column of pixel driving circuits distributed in the second direction Y can be correspondingly provided with onr first initial connection line 3Vinit1 or one second initial connection line 3Vinit2. The orthographic projections of the first initial connection line 3Vinit1 and the second initial connection line 3Vinit2 on the base substrate can be alternately distributed in sequence along the first direction X. The power line 3VDD can be connected to the second conductive portion 22 and the twelfth active portion 712 through vias, respectively, to connect the second electrode of the capacitor C, the first electrode of the fifth transistor T5 and the first power supply terminal.

As shown in FIG. 20, FIG. 24, and FIG. 29, the first bridge portion 31 can be connected to the first conductive portion 11 and the ninth active portion 79 through vias, respectively, to connect the second electrode of the first transistor T1, the first electrode of the second transistor, and the gate of the driving transistor T3. Herein, an opening 221 is formed on the second conductive portion 22, and the orthographic projection of the via connected between the first conductive portion 11 and the first bridge portion 31 on the base substrate is located within the orthographic projection of the opening 221 on the base substrate. The second bridge portion 32 can be connected to the tenth active portion 710 through a via to connect the second electrode of the sixth transistor T6. The third bridge portion 33 can be connected to the seventeenth active portion 717 and the eighteenth active portion 718 through vias, respectively, to connect the second electrode of the fourth transistor T4 and the first electrode of the driving transistor T3. The fourth bridge portion 34 can be connected to the thirteenth active portion 713 through a via to connect the first electrode of the fourth transistor T4. The sixth bridge portion 36 can be connected to the first initial signal line 2Vinit1 and the eighth active portion 78 through vias, respectively, to connect the first electrode of the first transistor T1 and the first initial signal terminal. The seventh bridge portion 37 can be connected to the second initial signal line 2Vinit2 and the eleventh active portion 711 through vias, respectively, to connect the first electrode of the seventh transistor T7 and the second initial signal terminal. The first initial connection line 3Vinit1 can be connected, through the sixth bridge portion 36, to the first initial signal line 2Vinit1 having their orthographic projections on the base substrate intersecting with each other, so as to form a grid structure of the first initial signal line 2Vinit1, which can reduce the self-resistance of the first initial signal line 2Vinit1, thereby improving the voltage uniformity of the first initial signal terminal connected to the pixel driving circuit at different positions of the display panel. The second initial connection line 3Vinit2 can be connected, through the seventh bridge portion 37, to the second initial signal line 2Vinit2 having their orthographic projections on the base substrate intersecting with each other, so as to form a grid structure of the second initial signal line 2Vinit2, which can reduce the self-resistance of the second initial signal line 2Vinit2, thereby improving the voltage uniformity of the second initial signal terminal connected to the pixel driving circuit at different positions of the display panel.

As shown in FIG. 20, FIG. 25, and FIG. 30, the fourth conductive layer may include: a data line Da, a power connection line 4VDD, and a fifth bridge portion 45. The orthographic projections of the data line Da and the power connection line 4VDD on the base substrate extend along the second direction. The data line Da is used to provide the data signal terminal in FIG. 1. The data line Da can be connected to the fourth bridge portion 34 through a via to connect the first electrode of the fourth transistor T4. The power connection line 4VDD can be connected to the power line 3VDD through a via to form a double-layer power line. This setting can reduce the self-resistance of the power line, thereby improving the uniformity of the voltage of the first power supply terminal at different positions of the display panel. The fifth bridge portion 45 can be connected to the second bridge portion 32 through a via to connect the second electrode of the sixth transistor T6.

As shown in FIG. 20 and FIG. 26, the electrode layer includes a plurality of electrode portions: a first electrode portion G, a second electrode portion B, and a third electrode portion R, each of which can be connected to the fifth bridge portion 45 through a via to connect the second electrode of the sixth transistor. In particular, FIG. 26 shows more electrode portions corresponding to pixel driving circuits compared to FIG. 30. The display panel may also include a pixel definition layer located on the side of the electrode layer away from the base substrate, and a plurality of pixel openings PH are formed on the pixel definition layer. The pixel openings PH are arranged corresponding to the electrode portions, and the orthographic projection of the pixel openings PH on the base substrate coincides with the orthographic projection of the electrode portions on the base substrate. The first electrode portion G can be used to form the electrode portion of the green light-emitting unit in the display panel, the second electrode portion B can be used to form the electrode portion of the blue light-emitting unit in the display panel, and the third electrode portion R can be used to form the electrode portion of the red light-emitting unit. Among the multiple electrode portions connected to the same row of pixel driving circuits, the second electrode portion B, the first electrode portion G, the third electrode portion R, and the first electrode portion G are alternately distributed in sequence in the row direction X. In two adjacent columns of pixel driving circuits, the multiple second electrode portions B and the multiple third electrode portions R are connected to the same column of pixel driving circuits, and the second electrode portions B and the third electrode portions R connected to the same column of pixel driving circuits are alternately distributed in sequence in the column direction Y; the multiple first electrode portions G are connected to another column of pixel driving circuits, and the first electrode portions G connected to the same column of pixel driving circuits are spaced apart in the column direction.

As shown in FIG. 20, FIG. 25, FIG. 26, and FIG. 30, the fifth bridge portion 45 can raise the left side of the first electrode portion G, thereby affecting the flatness of the first electrode portion G. In some exemplary embodiments, the fourth conductive layer may further include a sixth conductive portion 46. In the same pixel driving circuit, the sixth conductive portion 46 is connected to the side of the power connection line 4VDD away from the fifth bridge portion 45. The orthographic projection of the first electrode portion G on the base substrate overlaps with the orthographic projections of the sixth conductive portion 46 and the fifth bridge portion 45 on the base substrate. The sixth conductive portion 46 and the fifth bridge portion 45 overlap with the left and right sides of the first electrode portion G, respectively, so that the symmetry on the left and right sides of the first electrode portion G can be improved, thereby improving the flatness of the first electrode portion G.

As shown in FIG. 20, FIG. 25, FIG. 26, and FIG. 30, a partial structure of the fourth conductive layer is connected to a partial structure of the third conductive layer through a via. The orthographic projection of the via connected between the fourth conductive layer and the third conductive layer on the base substrate and the orthographic projection of each electrode portion on the base substrate do not overlap. This setting can improve the flatness of the electrode portion.

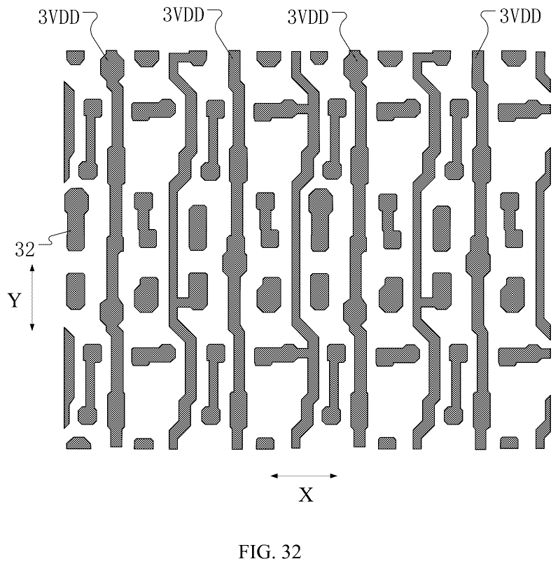

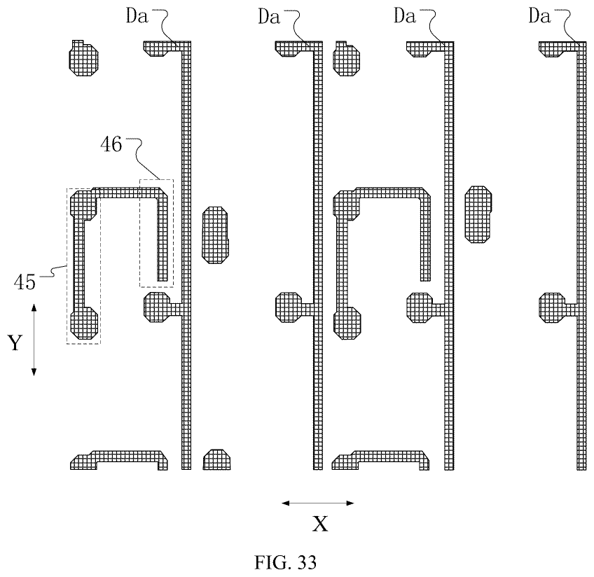

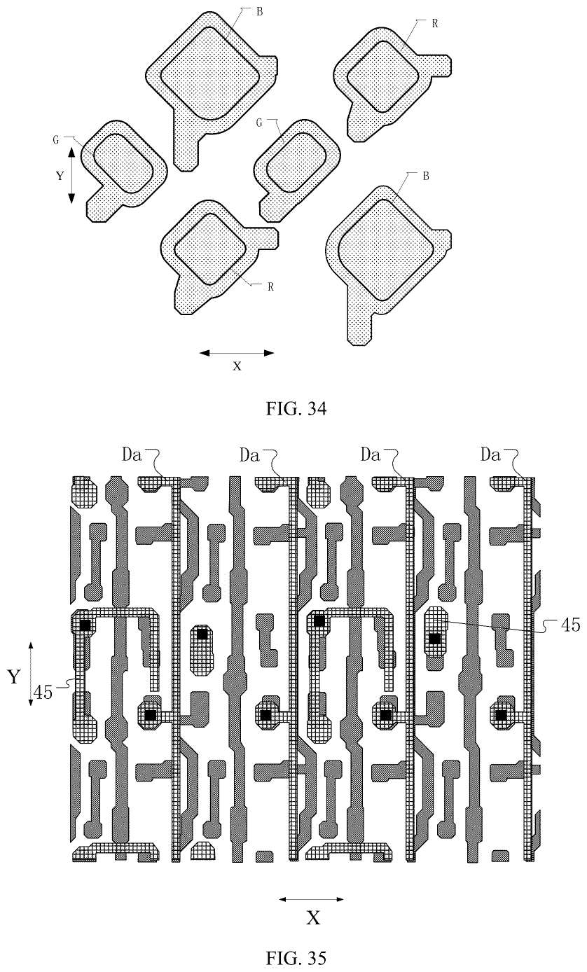

As shown in FIG. 31 to FIG. 35, FIG. 31 is a structural diagram of a display panel according to another exemplary embodiment of this disclosure. FIG. 31 only shows the third conductive layer, the fourth conductive layer, and the electrode in the display panel. FIG. 32 is a structural layout of the third conductive layer in FIG. 31; FIG. 33 is a structural layout of the fourth conductive layer in FIG. 31; FIG. 34 is a structural diagram of the electrode layer in FIG. 31; and FIG. 35 is a structural layout of the third conductive layer and the fourth conductive layer in FIG. 31.

Compared with the display panel shown in FIG. 20, the display panel shown in FIG. 31 does not have a power connection line 4VDD in the fourth conductive layer. In the display panel shown in FIG. 31, the sixth conductive portion 46 is connected to the fifth bridge portion 45 in the same layer. The sixth conductive portion 46 and the fifth bridge portion 45 overlap the left and right sides of the first electrode portion G respectively. This arrangement can improve the symmetry on the left and right sides of the first electrode portion G, thereby improving the flatness of the first electrode portion G.

In some exemplary embodiments, the display panel shown in FIG. 20 and FIG. 31 may also include a buffer layer, a first insulating layer, a second insulating layer, a first dielectric layer, a passivation layer, a first planarization layer, and a second planarization layer, where the base substrate, the buffer layer, the active layer, the first insulating layer, the first conductive layer, the second insulating layer, the second conductive layer, the first dielectric layer, the third conductive layer, the passivation layer, the first planarization layer, the fourth conductive layer, the second planarization layer, and the electrode layer are stacked in sequence. The first insulating layer and the second insulating layer may be silicon oxide layers, the first dielectric layer may be a silicon nitride layer, the passivation layer and the buffer layer may be made of silicon oxide, silicon nitride, or the like, and the first planarization layer and the second planarization layer may be made of organic materials, such as polyimide (PI), polyethylene terephthalate (PET), polyethylene naphthalate (PEN), silicon-glass bonding structure (SOG), or the like. The base substrate may include a glass substrate, a barrier layer, and a polyimide layer stacked in sequence, where the barrier layer may be an inorganic material. The material of the first conductive layer and the second conductive layer may be one of molybdenum, aluminum, copper, titanium, niobium or an alloy thereof, or a molybdenum/titanium alloy or laminate, or the like. The material of the third conductive layer and the fourth conductive layer may include a metal material, for example, one of molybdenum, aluminum, copper, titanium, niobium or an alloy thereof, or a molybdenum/titanium alloy or laminate, or a titanium/aluminum/titanium laminate, or the like. The square resistance of any layer of the first conductive layer and the second conductive layer may be greater than the square resistance of any layer of the third conductive layer and the fourth conductive layer.

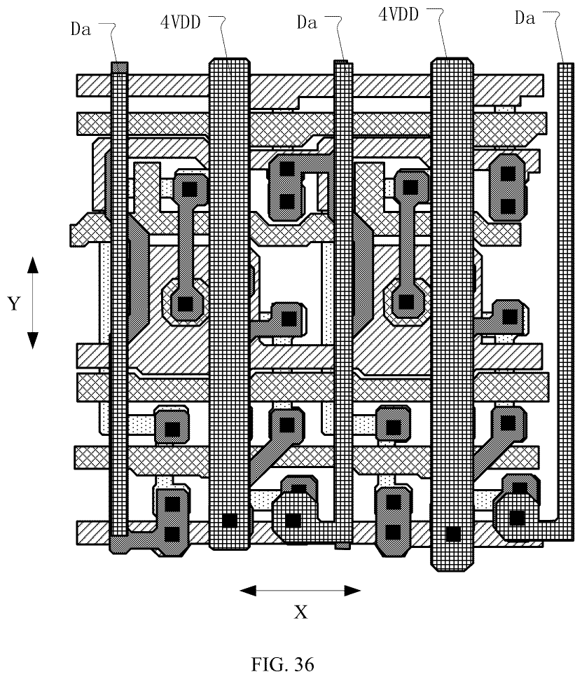

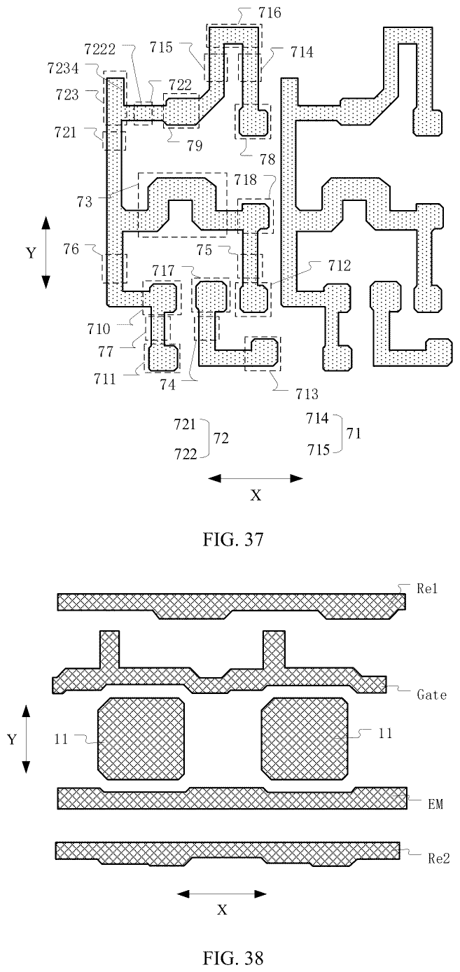

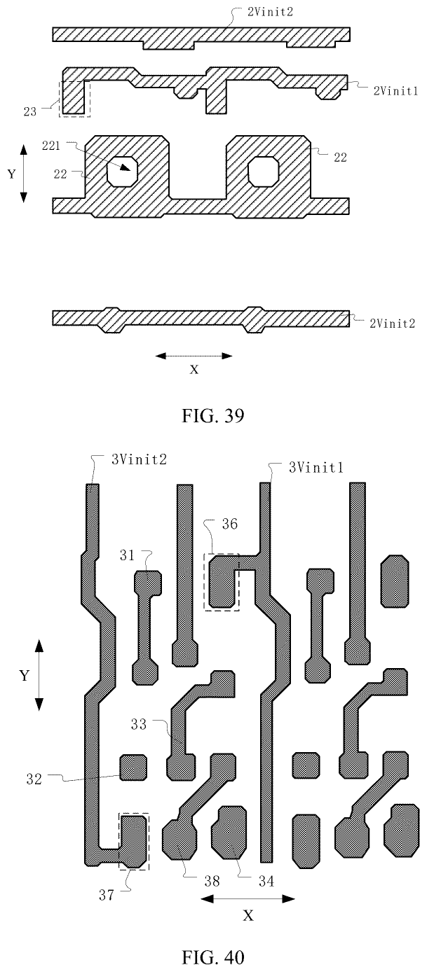

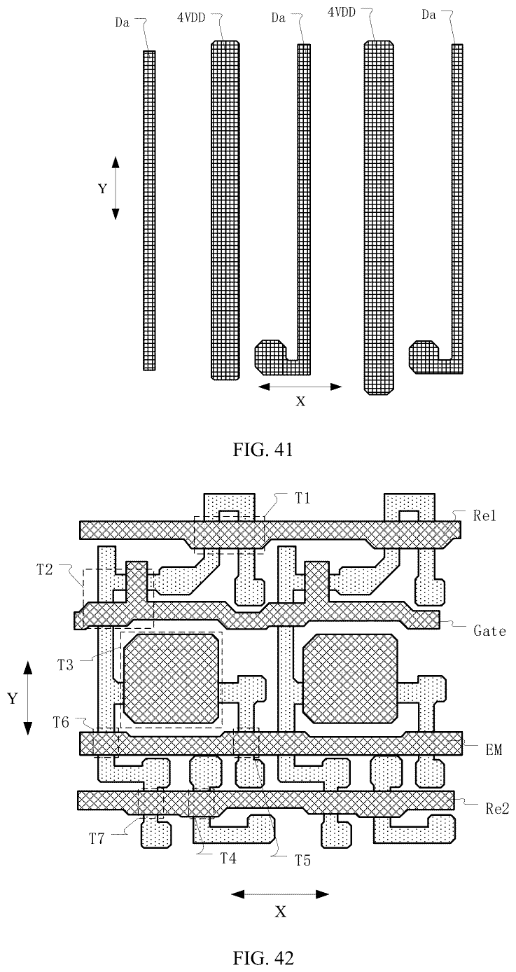

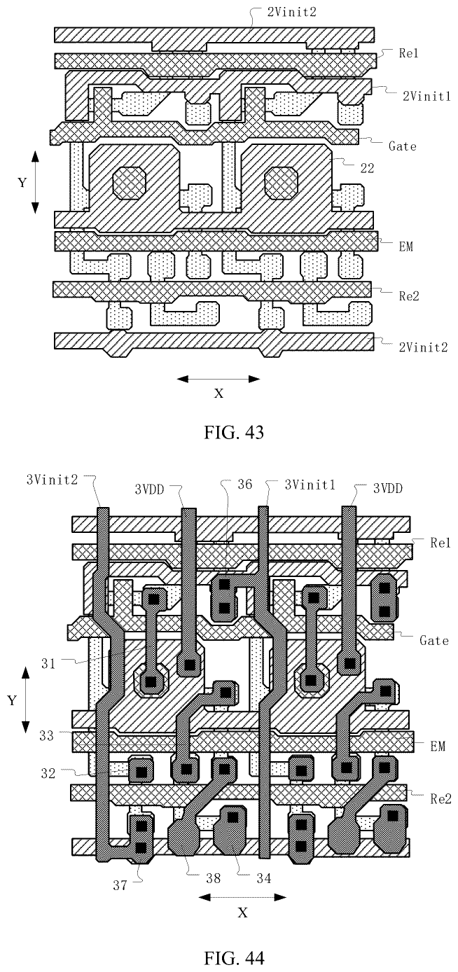

Some exemplary embodiments also provide another display panel, which may include a plurality of pixel driving circuits shown in FIG. 1. In some exemplary embodiments, the display panel may also include a substrate, an active layer, a first conductive layer, a second conductive layer, a third conductive layer, and a fourth conductive layer stacked in sequence, and an insulating layer(s) may be provided between the above structural layers. As shown in FIG. 36 to FIG. 44, FIG. 36 is a structural diagram of a display panel according to another exemplary embodiment of this disclosure; FIG. 37 is a structural layout of the active layer in FIG. 36; FIG. 38 is a structural layout of the first conductive layer in FIG. 36; FIG. 39 is a structural layout of the second conductive layer in FIG. 36; FIG. 40 is a structural layout of the third conductive layer in FIG. 36; FIG. 41 is a structural layout of the fourth conductive layer in FIG. 36; FIG. 42 is a structural layout of the active layer and the first conductive layer in FIG. 36; FIG. 43 is a structural layout of the active layer, the first conductive layer, and the second conductive layer in FIG. 36; FIG. 44 is a structural layout of the active layer, the first conductive layer, the second conductive layer, and the third conductive layer in FIG. 36.

As shown in FIG. 36, FIG. 37, and FIG. 42, the active layer may include a first active portion 71, a second active portion 72, a third active portion 73, a fourth active portion 74, a fifth active portion 75, a sixth active portion 76, and a seventh active portion 77. The first active portion 71 is used to form a channel region of the first transistor T1, the second active portion 72 is used to form a channel region of the second transistor T2, the third active portion 73 is used to form a channel region of the driving transistor T3, the fourth active portion 74 is used to form a channel region of the fourth transistor T4, the fifth active portion 75 is used to form a channel region of the fifth transistor T5, the sixth active portion 76 is used to form a channel region of the sixth transistor T6, and the seventh active portion 77 is used to form a channel region of the seventh transistor T7. The first active portion 71 includes a fourth active sub-portion 714 and a fifth active sub-portion 715, and the active layer further includes a sixth active sub-portion connected between the fourth active sub-portion 714 and the fifth active sub-portion 715. The second active portion 72 includes a first active sub-portion 721 and a second active sub-portion 722, and the active layer further includes a third active sub-portion 723 connected between the first active sub-portion 721 and the second active sub-portion 722. As shown in FIG. 3, FIG. 4, and FIG. 10, the active layer may further include an eighth active portion 78, a ninth active portion 79, a tenth active portion 710, an eleventh active portion 711, a twelfth active portion 712, a thirteenth active portion 713, a seventeenth active portion 717, and an eighteenth active portion 718. The eighth active portion 78 is connected to one end of the first active portion 71 away from the second active portion 72. The ninth active portion 79 is connected between the first active portion 71 and the second active portion 72. The tenth active portion 710 is connected between the sixth active portion 76 and the seventh active portion 77. The eleventh active portion 711 is connected to one end of the seventh active portion 77 away from the sixth active portion 76. The twelfth active portion 712 is connected to one end of the fifth active portion 75 away from the third active portion 73. The thirteenth active portion 713 and the seventeenth active portion 717 are connected to two ends of the fourth active portion 74. The eighteenth active portion 718 is connected between the fifth active portion 75 and the third active portion 73.

As shown in FIG. 36, FIG. 38 and FIG. 42, the first conductive layer includes a first conductive portion 11, a gate line Gate, a first reset signal line Re1, a second reset signal line Re2 and an enable signal line EM. The orthographic projections of the gate line Gate, the first reset signal line Re1, the second reset signal line Re2 and the enable signal line EM on the base substrate extend along the first direction X. The gate line Gate is used to provide the gate driving signal in FIG. 1, the first reset signal line Re1 is used to provide the first reset signal terminal in FIG. 1, the second reset signal line Re2 is used to provide the second reset signal terminal in FIG. 1, and the enable signal line EM is used to provide the enable signal terminal in FIG. 1. The orthographic projection of the gate line Gate on the base substrate covers the orthographic projection of the second active portion 72 on the base substrate, and a partial structure of the gate line Gate is used to form the gate of the second transistor T2. The orthographic projection of the first reset signal line Re1 on the base substrate covers the orthographic projection of the first active portion 71 on the base substrate, and a partial structure of the first reset signal line Re1 is used to form the gate of the first transistor T1. The orthographic projection of the second reset signal line Re2 on the base substrate covers the orthographic projections of the fourth active portion 74 and the seventh active portion 77 on the base substrate, and a partial structure of the second reset signal line Re2 is used to form the gates of the fourth transistor T4 and the seventh transistor T7, respectively. The orthographic projection of the enable signal line EM on the base substrate covers the orthographic projections of the fifth active portion 75 and the sixth active portion 76 on the base substrate, and a partial structure of the enable signal line EM is used to form the gates of the fifth transistor T5 and T6, respectively. The orthographic projection of the first conductive portion 11 on the base substrate covers the orthographic projection of the third active portion 73 on the base substrate, and the first conductive portion 11 is used to form the gate of the driving transistor T3 and the first electrode of the capacitor C.

As shown in FIG. 36, FIG. 38, and FIG. 43, the second conductive layer may include a first initial signal line 2Vinit 1, a second initial signal line 2Vinit2, a second conductive portion 22, and a third conductive portion 23. The first initial signal line 2Vinit1 may be used to provide the first initial signal terminal in FIG. 1, and the second initial signal line 2Vinit2 may be used to provide the second initial signal terminal in FIG. 1. The orthographic projection of the first initial signal line 2Vinit1 on the base substrate and the orthographic projection of the second initial signal line 2Vinit2 on the base substrate may both extend along the first direction X. The orthographic projection of the second conductive portion 22 on the base substrate may at least partially overlap with the orthographic projection of the first conductive portion 11 on the base substrate, and the second conductive portion 22 may be used to form the second electrode of the capacitor C, where a plurality of second conductive portions 22 distributed in the first direction X may be connected in sequence. The orthographic projection of the third conductive portion 23 on the base substrate at least partially overlaps with the orthographic projection of the third active sub-portion 723 on the base substrate, and the third conductive portion 23 can be connected to the first initial signal line 2Vinit1. The third conductive portion 23 can stabilize the voltage of the third active sub-portion 723, thereby improving the problem of leakage to the source and drain of the second transistor T2 caused by the voltage change of the third active sub-portion 723.

As shown in FIG. 36, FIG. 37 and FIG. 42, the second active sub-portion 722 as a channel region includes a second side 7222 extending along the length direction of the channel region, and the third active sub-portion 723 includes a fourth side 7234. The fourth side 7234 is connected to the second side 7222, and an angle formed by the fourth side 7234 and the second side 7222 is less than 180°. In other words, the third active sub-portion 723 has an enlarged configuration, which can increase the overlapping area between the orthographic projections of the third active sub-portion 723 and the third conductive portion 23 on the base substrate, thereby improving the voltage stabilizing effect of the third conductive portion 23 on the third active sub-portion 723.

As shown in FIG. 36, FIG. 37 and FIG. 42, in the first direction X, the orthographic projection of the fourth active portion 74 on the base substrate is located between the orthographic projection of at least partial structure of the third active portion 73 on the base substrate and the orthographic projection of the fifth active portion 75 on the base substrate.

In some exemplary embodiments, the fifth transistor T5 is disposed on a side of the fourth transistor T4 away from the driving transistor T3, so that a larger design space can be reserved for the capacitor C. A larger capacitor C can be beneficial to mitigating the low-frequency flicker of the display panel and improving the low grayscale image quality. In addition, the fifth transistor T5 is disposed on the side of the fourth transistor T4 away from the driving transistor T3, so a partial structure of the first electrode of the fifth transistor located in the active layer can be arranged without bending, thereby being beneficial to the spatial design of the display panel layout.

As shown in FIG. 36, FIG. 40, and FIG. 44, the third conductive layer may include a power line 3VDD, a first initial connection line 3Vinit1, a second initial connection line 3Vinit2, a first bridge portion 31, a second bridge portion 32, a third bridge portion 33, a fourth bridge portion 34, a sixth bridge portion 36, a seventh bridge portion 37, and an eighth bridge portion 38. The power line 3VDD can be used to provide the first power terminal in the pixel driving circuit shown in FIG. 1. The orthographic projections of the power line 3VDD, the first initial connection line 3Vinit1, and the second initial connection line 3Vinit2 on the base substrate can extend along the second direction Y. A column of pixel driving circuits distributed in the second direction Y can be correspondingly provided with one first initial connection line 3Vinit1 or one second initial connection line 3Vinit2. The orthographic projections of the first initial connection line 3Vinit1 and the second initial connection line 3Vinit2 on the base substrate can be alternately distributed in sequence along the first direction X. The power line 3VDD can be connected to the second conductive portion 22 through a via to connect the second electrode of the capacitor C and the first power terminal.

As shown in FIG. 36, FIG. 40, and FIG. 44, the first bridge portion 31 can be connected to the first conductive portion 11 and the ninth active portion 79 through vias, respectively, to connect the second electrode of the first transistor T1, the first electrode of the second transistor, and the gate of the driving transistor T3. An opening 221 is formed on the second conductive portion 22, and the orthographic projection of the via connected between the first conductive portion 11 and the first bridge portion 31 on the base substrate is located within the orthographic projection of the opening 221 on the base substrate. The second bridge portion 32 can be connected to the tenth active portion 710 through a via to connect the second electrode of the sixth transistor T6. The third bridge portion 33 can be connected to the seventeenth active portion 717 and the eighteenth active portion 718 through vias, respectively, to connect the second electrode of the fourth transistor T4 and the first electrode of the driving transistor T3. The fourth bridge portion 34 can be connected to the thirteenth active portion 713 through a via to connect the first electrode of the fourth transistor T4. The sixth bridge portion 36 can be connected to the first initial signal line 2Vinit1 and the eighth active portion 78 through vias, respectively, to connect the first electrode of the first transistor T1 and the first initial signal terminal. The seventh bridge portion 37 can be connected to the second initial signal line 2Vinit2 and the eleventh active portion 711 through vias, respectively, to connect the first electrode of the seventh transistor T7 and the second initial signal terminal. The first initial connection line 3Vinit1 can be connected, through the sixth bridge portion 36, to the first initial signal line 2Vinit1 intersecting with its orthographic projection on the base substrate, so as to form a grid structure with the first initial signal line 2Vinit1, thereby reducing the self-resistance of the first initial signal line 2Vinit1 and, thus, improving the voltage uniformity of the first initial signal terminal connected to the pixel driving circuits at different positions of the display panel. The second initial connection line 3Vinit2 can be connected, through the seventh bridge portion 37, to the second initial signal line 2Vinit2 intersecting with its orthographic projection on the base substrate, so as to form a grid structure with the second initial signal line 2Vinit2, thereby reducing the self-resistance of the second initial signal line 2Vinit2 and, thus, improving the voltage uniformity of the second initial signal terminal connected to the pixel driving circuits at different positions of the display panel. The eighth bridge portion 38 can be connected to the twelfth active portion 712 through a via to connect the first electrode of the fifth transistor T5.

As shown in FIG. 36 and FIG. 41, the fourth conductive layer may include: a data line Da and a power connection line 4VDD. The orthographic projections of the data line Da and the power connection line 4VDD on the base substrate extend along the second direction. The data line Da is used to provide the data signal terminal in FIG. 1. The data line Da may be connected to the fourth bridge portion 34 through a via to connect the first electrode of the fourth transistor T4. The power connection line 4VDD may be connected to the power line 3VDD through a via to form a double-layer power line. This setting can reduce the self-resistance of the power line, thereby improving the voltage uniformity of the first power terminal at different positions of the display panel.

In some exemplary embodiments, the display panel shown in FIG. 36 may also include a buffer layer, a first insulating layer, a second insulating layer, a first dielectric layer, a passivation layer, a first planarization layer, a second planarization layer, and an electrode layer, where the base substrate, the buffer layer, the active layer, the first insulating layer, the first conductive layer, the second insulating layer, the second conductive layer, the first dielectric layer, the third conductive layer, the passivation layer, the first planarization layer, the fourth conductive layer, the second planarization layer, and the electrode layer are stacked in sequence. The first insulating layer and the second insulating layer may be silicon oxide layers. The first dielectric layer may be a silicon nitride layer. The passivation layer and the buffer layer may be made of silicon oxide, silicon nitride, or the like. The first planarization layer and the second planarization layer may be made of organic materials, such as polyimide (PI), polyethylene terephthalate (PET), polyethylene naphthalate (PEN), silicon-glass bonding structure (SOG) and other materials. The base substrate may include a glass substrate, a barrier layer, and a polyimide layer stacked in sequence, and the barrier layer may be an inorganic material. The material of the first conductive layer and the second conductive layer may be one of molybdenum, aluminum, copper, titanium, niobium or an alloy thereof, or a molybdenum/titanium alloy or laminate, or the like. The material of the third conductive layer and the fourth conductive layer may include a metal material, for example, one of molybdenum, aluminum, copper, titanium, niobium or an alloy thereof, or a molybdenum/titanium alloy or laminate, or a titanium/aluminum/titanium laminate, or the like. Herein, the square resistance of any layer of the first conductive layer and the second conductive layer may be greater than the square resistance of any layer of the third conductive layer and the fourth conductive layer.

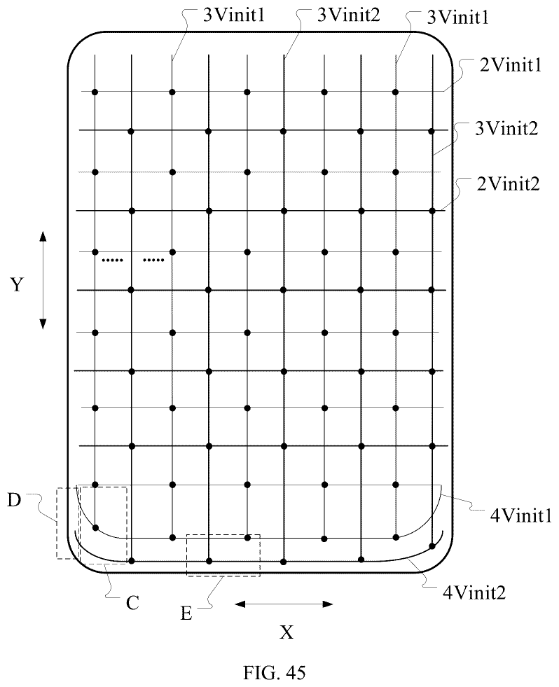

As shown in FIG. 45, it is a schematic structural diagram of a display panel according to an exemplary embodiment of this disclosure. The display panel may also have a first initial routing line 4Vinit1 and a second initial routing line 4Vinit2. The orthographic projections of the first initial routing line 4Vinit1 and the second initial routing line 4Vinit2 on the base substrate extend along the first direction X. The orthographic projections of the first initial routing line 4Vinit1 and the second initial routing line 4Vinit2 on the base substrate are located on a side, in the second direction Y, of the orthographic projections of the first initial connection line 3Vinit1 and the second initial connection line 3Vinit 2 on the base substrate. The first initial routing line 4Vinit1 is connected to multiple first initial connection lines 3Vinit1, and the second initial routing line 4Vinit2 is connected to multiple second initial connection lines 3 Vinit1.

Since the square resistance of the third conductive layer is smaller than that of the second conductive layer, initial signals are provided to the first initial connection line 3Vinit1 and the second initial connection line 3Vinit2 with smaller square resistance respectively through the first initial routing line 4Vinit1 and the second initial routing line 4Vinit2 according to some exemplary embodiments, thereby improving the writing speed of the initial signals.

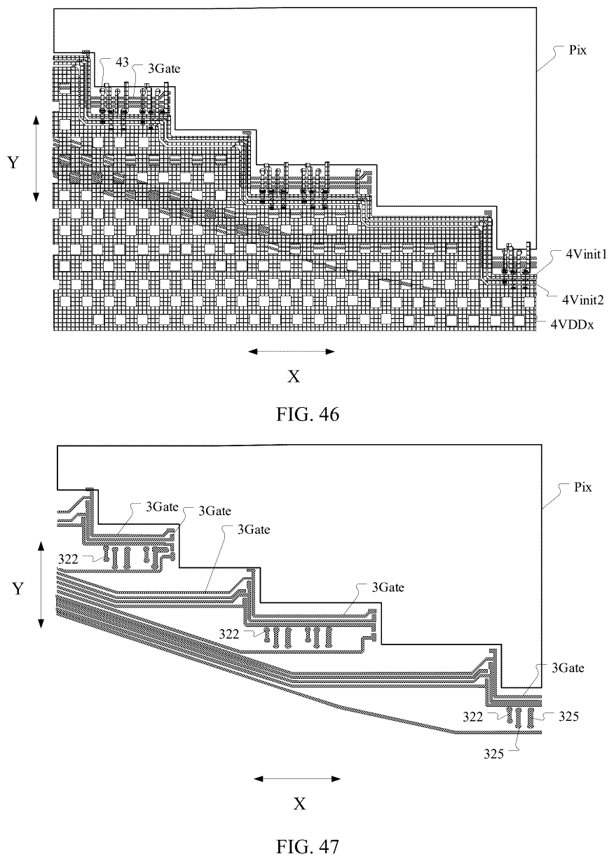

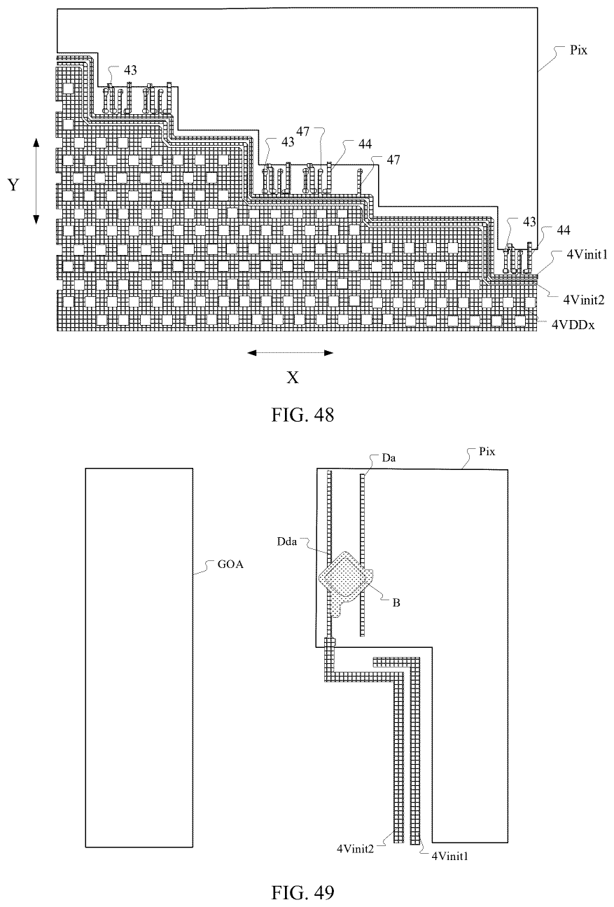

As shown in FIG. 46 to FIG. 48, FIG. 46 is an enlarged view of the local area C in FIG. 45, FIG. 47 is a structural layout of the third conductive layer in FIG. 46, and FIG. 48 is a structural layout of the fourth conductive layer in FIG. 46. In some exemplary embodiments, the third conductive layer may also include: a plurality of gate line access lines 3Gate, a second connection portion 322. The orthographic projections of the plurality of gate line access lines 4Gate on the base substrate extend along the first direction X and are spaced apart along the second direction, and the gate line access lines 4Gate are connected between the gate driving circuit and the pixel driving circuit. The gate driving circuit can provide a gate driving signal to the first reset signal line, the second reset signal line, the enable signal line and other gate lines located in the pixel area Pix through the gate line access lines 4Gate, and the pixel area Pix is used to integrate the pixel driving circuits. As shown in FIG. 46 to FIG. 48, the first initial routing line 4Vinit1 and the second initial routing line 4Vinit2 located in the rounded corner area of the display panel are located in the fourth conductive layer. In the rounded corner area of the display panel, the orthographic projections of the first initial routing line 4Vinit1 and the second initial routing line 4Vinit2 on the base substrate are bent and extended along the first direction X. The orthographic projections of the first initial routing line 4Vinit1 and the second initial routing line 4Vinit2 on the base substrate are located between the orthographic projections of two adjacent gate line access lines 4Gate on the base substrate. The orthographic projection of the second connection portion 322 on the base substrate extends along the second direction Y and intersects with the orthographic projection of the first initial routing line 4Vinit1 on the base substrate. The second connection portion 322 is connected between the second initial routing line 4Vinit2 and the second initial connection line 3Vinit2. The fourth conductive layer further includes: a third connection portion 43, the orthographic projection of the third connection portion 43 on the base substrate extends along the second direction Y and intersects with the orthographic projection of part of the gate line access line 4Gate on the base substrate, and the third connection portion 43 is connected between the second connection portion 322 and the second initial connection line 3Vinit2 located in the pixel area Pix. The first initial wiring 4Vinit1 can be connected to the first initial connection line located in the pixel area Pix through the seventh connection portion 47 connected to the first initial wiring 4Vinit1 in the same layer.

As shown in FIG. 46-FIG. 48, the fourth conductive layer may further include a power access line 4VDDx, which may be connected to the power connection line 4VDD located in the pixel area Pix via a fifth connection portion 325 located in the third conductive layer and a fourth connection portion 44 located in the fourth conductive layer.

As shown in FIG. 3 and FIG. 20, the orthographic projection of the second electrode portion B on the base substrate overlaps with the orthographic projections of two adjacent data lines Da on the base substrate, and the orthographic projections of the two data lines Da adjacent in the first direction X on the base substrate are respectively arranged close to two sides, in the first direction, of the orthographic projections of the overlapping electrode portion on the base substrate. This arrangement can improve the left-right symmetry of the second electrode portion B, thereby improving the flatness of the second electrode portion B. It should be understood that in other exemplary embodiments, two adjacent data lines may also overlap with other electrode portions to improve the flatness of the overlapping electrode portion.

As shown in FIG. 49, which is an enlarged view of the local area D in FIG. 45, the display panel also includes a gate driving circuit GOA and a plurality of pixel driving circuits. The fourth conductive layer also includes: an analog data line Dda. The orthographic projection of the analog data line Dda on the base substrate extends along the second direction Y, and the orthographic projection of the analog data line Dda on the base substrate is located between the orthographic projection of the gate driving circuit GOA on the base substrate and the orthographic projection of the data line Da closest to the gate driving circuit GOA on the base substrate. The orthographic projections of the analog data line Dda and its adjacent data line Da on the base substrate overlap with the orthographic projection of the second electrode portion B on the base substrate, and the orthographic projections, on the base substrate, of the analog data line Dda and data line Da adjacent in the first direction X are respectively arranged close to two sides, in the first direction, of the orthographic projection of the overlapping second electrode portion B on the base substrate. In some exemplary embodiments, the flatness of the electrode portion on the side closest to the gate driving circuit can be improved by adding the analog data line Dda.

In some exemplary embodiments, as shown in FIG. 49, the second initial routing line 4Vinit2 can be connected to the analog data line Dda, and the analog data line Dda can be connected to multiple second initial signal lines located in the pixel area Pix through vias. This setting can also increase the access points of the second initial signal line on the left and right sides of the display panel, thereby further improving the writing speed of the initial signals.

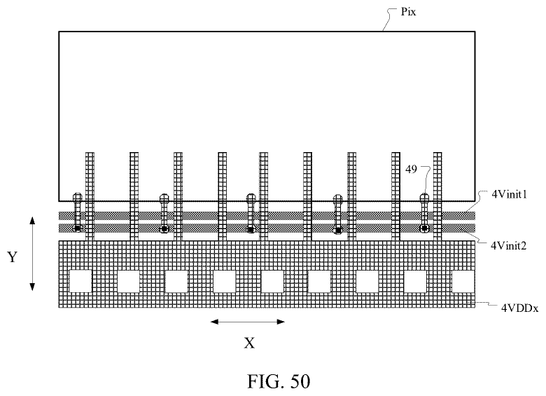

As shown in FIG. 50, which is an enlarged view of the local area E in FIG. 45, in the straight area of the lower frame of the display panel, the first initial routing line 4Vinit1 and the second initial routing line 4Vinit2 are located in the third conductive layer; and in the straight area of the display panel, the orthographic projections of the first initial routing line 4Vinit1 and the second initial routing line 4Vinit2 on the base substrate extend straightly along the first direction. The second initial routing line 4Vinit2 can be connected to the second initial connection line located in the pixel area Pix through the ninth connection portion 49 located in the fourth conductive layer.

It should be noted that, in some exemplary embodiments, the positions of the first initial routing line 4Vinit1 and the second initial routing line 4Vinit2 can also be swapped, that is, the orthographic projection of the first initial routing line 4Vinit1 on the base substrate is located on the side of the orthographic projection of the second initial routing line 4Vinit2 on the base substrate away from the orthographic projection of the first initial connection line on the base substrate.

It should be noted that, in some exemplary embodiments, the black squares illustrated on the side of the third conductive layer away from the base substrate represent the vias through which the third conductive layer is connected to other layers on the side facing the base substrate; the black squares illustrated on the side of the fourth conductive layer away from the base substrate represent the vias through which the fourth conductive layer is connected to other layers on the side facing the base substrate; and the black squares illustrated on the side of the electrode layer away from the base substrate represent the vias through which the electrode layer is connected to the side facing the base substrate. The black squares represent the positions of the vias, and different vias represented by black squares at different positions may penetrate different insulating layers.

It should be noted that the proportions of the drawings in this disclosure can be used as a reference in the actual process, but are not limited thereto. For example, the width-to-length ratio of the channel, the thickness and spacing of each film layer, and the width and spacing of each signal line can be adjusted according to actual needs. The number of pixels in the display substrate and the number of sub-pixels in each pixel are not limited to the numbers shown in the drawings. The drawings described in this disclosure are not limited to the numbers shown in the drawings. The drawings are only schematic diagrams of the structure. In addition, the “first”, “second” and the like are only used to define different structural names, without limiting a specific order and quantity. In some exemplary embodiments, when referring to that the orthographic projection of a certain structure on the base substrate extends in a certain direction, it can be understood as the orthographic projection of this structure on the base substrate extends in a straight line or in a bending manner along the direction. A transistor refers to an element including at least three terminals: a gate, a drain and a source. The transistor has a channel region between the drain (drain electrode terminal, drain region or drain electrode) and the source (source electrode terminal, source region or source electrode), and the current can flow through the drain, the channel region and the source. In some exemplary embodiments, the channel region refers to a region where the current mainly flows. In some exemplary embodiments, the first electrode can be the drain, the second electrode can be the source; or the first electrode can be the source, and the second electrode can be the drain. In the case of using transistors with opposite polarities or the current direction changes in the circuit operation, the functions of the “source” and the “drain” are sometimes interchanged. Therefore, in some exemplary embodiments, the “source” and the “drain” can be interchanged. In addition, the gate can also be called a control electrode.

Some exemplary embodiments also provide a display device, which includes the above-mentioned display panel. The display device can be a display device such as a mobile phone, a tablet computer, a television, or the like.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

Those skilled in the art will readily appreciate other embodiments of the present disclosure after considering the specification and practicing the invention disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

It should be understood that the present disclosure is not limited to the exact structures that have been described above and shown in the drawings, and that various modifications and changes may be made without departing from the scope thereof. The scope of the present disclosure is limited only by the appended claims.

1. A display panel, comprising:
a base substrate;
a plurality of first initial signal lines, wherein orthographic projections of the first initial signal lines on the base substrate extend along a first direction and are spaced apart along a second direction, and the first direction intersects with the second direction;
a plurality of second initial signal lines, located in a same conductive layer as the first initial signal lines, wherein orthographic projections of the second initial signal lines on the base substrate extend along the first direction and are spaced apart along the second direction;
a plurality of first initial connection lines, located in a different conductive layer from the first initial signal lines, wherein orthographic projections of the first initial connection lines on the base substrate extend along the second direction and are spaced apart along the first direction, and the first initial connection lines are connected, through vias, to at least part of the first initial signal lines with orthographic projections on the base substrate intersecting with the first initial connection lines; and
a plurality of second initial connection lines, located in a same conductive layer as the first initial connection lines, wherein orthographic projections of the second initial connection lines on the base substrate extend along the second direction and are spaced apart along the first direction, and the second initial connection lines are connected, through vias, to at least part of the second initial signal lines with orthographic projections on the base substrate intersecting with the second initial connection lines.

2. The display panel according to claim 1, further comprising:
a second conductive layer, located on a side of the base substrate, wherein the second conductive layer comprises the first initial signal lines and the second initial signal lines; and
a third conductive layer, located on a side of the second conductive layer away from the base substrate, wherein the third conductive layer comprises the first initial connection lines and the second initial connection lines.

3. The display panel according to claim 2, further comprising a pixel driving circuit, wherein the pixel driving circuit comprises a driving transistor, a first transistor, and a capacitor; a first electrode of the capacitor is connected to a gate of the driving transistor, a first electrode of the first transistor is connected to the first initial signal line, and a second electrode of the first transistor is connected to the gate of the driving transistor;
the display panel further comprises:
a first conductive layer, located between the second conductive layer and the base substrate, wherein the first conductive layer comprises a first conductive portion, and the first conductive portion is configured to form the gate of the driving transistor and the first electrode of the capacitor;
the second conductive layer further comprises:
a second conductive portion, wherein an orthographic projection of the second conductive portion on the base substrate at least partially overlaps with an orthographic projection of the first conductive portion on the base substrate, and the second conductive portion is configured to form a second electrode of the capacitor;
the third conductive layer further comprises:
a first bridge portion, wherein the first bridge portion is connected to the second electrode of the first transistor, and is connected to the first conductive portion through a via.

4. The display panel according to claim 1, further comprising a pixel driving circuit, wherein the pixel driving circuit comprises a driving transistor, a fourth transistor, and a second transistor;
the fourth transistor is provided with a first electrode connected to a data line, a second electrode connected to a first electrode of the driving transistor, and a gate connected to a second reset signal line; and
the second transistor is provided with a first electrode connected to a gate of the driving transistor, a second electrode connected to a second electrode of the driving transistor, and a gate connected to a gate line.

5. The display panel according to claim 1, further comprising a pixel driving circuit, wherein the pixel driving circuit comprises a driving transistor and a second transistor; a first electrode of the second transistor is connected to a gate of the driving transistor, and a second electrode of the second transistor is connected to a second electrode of the driving transistor;
the display panel further comprises:
an active layer, located on a side of the base substrate, wherein the active layer comprises a second active portion configured to form a channel region of the second transistor, the second active portion comprises a first active sub-portion and a second active sub-portion, and the active layer further comprises a third active sub-portion connected between the first active sub-portion and the second active sub-portion; and
a second conductive layer, located on a side of the active layer away from the base substrate, wherein the second conductive layer comprises a third conductive portion, an orthographic projection of the third conductive portion on the base substrate at least partially overlaps with an orthographic projection of the third active sub-portion on the base substrate, and the third conductive portion is connected to a stable voltage source.

6. The display panel according to claim 5, wherein the first active sub-portion serving as a channel region comprises a first side extending along a length direction of the channel region, the second active sub-portion serving as a channel region comprises a second side extending along a length direction of the channel region, and the third active sub-portion comprises a third side and a fourth side;
wherein, the third side is connected to the first side, and an angle formed by the third side and the first side is less than or equal to 180°;
and/or, the fourth side is connected to the second side, and an angle formed by the fourth side and the second side is less than or equal to 180°.

7. The display panel according to claim 5, wherein:
the display panel further comprises a power line, configured to provide a power signal to the pixel driving circuit, wherein the power line is connected to the third conductive portion through a via; or
the second conductive layer comprises the first initial signal line, and the first initial signal line and the third conductive portion are connected in the same layer; or
the pixel driving circuit further comprises a capacitor, and a first electrode of the capacitor is connected to the gate of the driving transistor; the second conductive layer further comprises: a second conductive portion, configured to form a second electrode of the capacitor; wherein the third conductive portion and the second conductive portion are connected in the same layer. cm. 8-9. (canceled)

10. The display panel according to claim 1, comprising pixel driving circuits arrayed in the first direction and the second direction, the pixel driving circuit comprises a driving transistor and a capacitor, and a first electrode of the capacitor is connected to a gate of the driving transistor;
the display panel further comprises:
a second conductive layer, comprising a second conductive portion and a fourth conductive portion, wherein the second conductive portion is configured to form a second electrode of the capacitor, and the fourth conductive portion is connected between second conductive portions adjacent to each other in the first direction; and a third conductive layer, located on a side of the second conductive layer away from the base substrate, wherein the third conductive layer comprises a power line, and the power line is configured to provide a power signal to the pixel driving circuit;
wherein, the power line comprises: a first extension portion, a second extension portion, and a third extension portion, and the third extension portion is connected between the first extension portion and the second extension portion;
an orthographic projection of the first extension portion on the base substrate and an orthographic projection of the second extension portion on the base substrate extend along the second direction, and an orthographic projection of the third extension portion on the base substrate extends along the first direction;
the orthographic projection of the third extension portion on the base substrate at least partially overlaps with an orthographic projection of the fourth conductive portion on the base substrate.

11. The display panel according to claim 2, further comprising:
a fourth conductive layer, located on a side of the third conductive layer away from the base substrate, wherein the fourth conductive layer comprises a plurality of data lines, and orthographic projections of the data lines on the base substrate extend along the second direction; wherein,
orthographic projections of part of the data lines on the base substrate at least partially overlap with the orthographic projections of the first initial connection lines on the base substrate; and/or,
orthographic projections of part of the data lines on the base substrate at least partially overlap with the orthographic projections of the second initial connection lines on the base substrate.

12. The display panel according to claim 11, wherein, among the data lines and the first initial connection lines with overlapped orthographic projections on the base substrate, an overlapping area between the orthographic projections of the data lines on the base substrate and the orthographic projections of the first initial connection lines on the base substrate is S1, an area of the orthographic projections of the data lines on the base substrate is S2, and S1/S2 is greater than or equal to 50%;
and/or, among the data lines and the second initial connection lines with overlapped orthographic projections on the base substrate, an overlapping area between the orthographic projections of the data lines on the base substrate and the orthographic projections of the second initial connection lines on the base substrate is S3, an area of the orthographic projections of the data lines on the base substrate is S4, and S3/S4 is greater than or equal to 50%.

13. The display panel according to claim 2, further comprising a pixel driving circuit, wherein the third conductive layer further comprises:
a first connection portion, wherein an orthographic projection of the first connection portion on the base substrate extends along the first direction, and the first connection portion is connected between the first initial connection line and the pixel driving circuit; and
a plurality of power lines, configured to provide a power signal to the pixel driving circuit;
wherein, part of the power lines comprise multiple power line segments spaced apart in the second direction, and the orthographic projection of the first connection portion on the base substrate is located between orthographic projections, on the base substrate, of adjacent power line segments in a same power line.

14. The display panel according to claim 1, further comprising:
a third conductive layer, located on a side of the base substrate;
a fourth conductive layer, located on a side of the third conductive layer away from the base substrate, wherein a partial structure of the fourth conductive layer is connected to a partial structure of the third conductive layer through a via;
an electrode layer, located on a side of the fourth conductive layer away from the base substrate, wherein the electrode layer comprising a plurality of electrode portions; and
a pixel definition layer, located on a side of the electrode layer away from the base substrate, wherein a plurality of pixel openings are formed on the pixel definition layer and arranged corresponding to the electrode portions, and orthographic projections of the pixel openings on the base substrate coincide with orthographic projections of the corresponding electrode portions on the base substrate;
wherein, an orthographic projection of the via connected between the third conductive layer and the fourth conductive layer on the base substrate does not overlap with the orthographic projections of the electrode portions on the base substrate.

15. The display panel according to claim 1, further comprising:
a fourth conductive layer, located on a side of the base substrate, wherein the fourth conductive layer comprises a plurality of fifth bridge portions;
an electrode layer, located on a side of the fourth conductive layer away from the base substrate, wherein the electrode layer comprises a plurality of electrode portions arranged corresponding to the fifth bridge portions, and the electrode portions are connected to the corresponding fifth bridge portions through vias; and
a pixel definition layer, located on a side of the electrode layer away from the base substrate, wherein a plurality of pixel openings are formed on the pixel definition layer and arranged corresponding to the electrode portions, and orthographic projections of the pixel openings on the base substrate coincide with orthographic projections of the corresponding electrode portions on the base substrate;
wherein the fourth conductive layer further comprises a sixth conductive portion, and orthographic projections of part of the electrode portions on the base substrate overlap with an orthographic projection of the sixth conductive portion on the base substrate and an orthographic projection of the fifth bridge portion on the base substrate respectively; and
the orthographic projection of the sixth conductive portion on the base substrate is arranged close a side, in the first direction, of the orthographic projection of the electrode portion on the base substrate, and the orthographic projection of the fifth bridge portion on the base substrate is arranged on another side, in the first direction, of the orthographic projection of the electrode portion on the base substrate.

16. The display panel according to claim 15, further comprising a pixel driving circuit, wherein the fourth conductive layer further comprises:
a power connection line, wherein an orthographic projection of the power connection line on the base substrate extends along the second direction, and the power connection line is configured to provide a power signal to the pixel driving circuit;
wherein the sixth conductive portion is connected to the power connection line, the orthographic projection of the power connection line on the base substrate is located between the orthographic projection of the sixth conductive portion on the base substrate and the orthographic projection of the fifth bridge part on the base substrate, and the orthographic projection of the power connection line on the base substrate overlaps with the orthographic projection of the electrode portion on the base substrate.

17. (canceled)

18. The display panel according to claim 1, wherein the display panel further comprises a pixel driving circuit, and the pixel driving circuit comprises a driving transistor, a fourth transistor, and a fifth transistor;
a first electrode of the fourth transistor is connected to a data line, and a second electrode of the fourth transistor is connected to a first electrode of the driving transistor;
a first electrode of the fifth transistor is connected to a power line, and a second electrode of the fifth transistor is connected to the first electrode of the driving transistor;
the display panel further comprises:
an active layer, located on a side of the base substrate, wherein the active layer comprises a third active portion, a fourth active portion, and a fifth active portion,
the third active portion is configured to form a channel region of the driving transistor, the fourth active portion is configured to form a channel region of the fourth transistor, and the fifth active portion is configured to form a channel region of the fifth transistor; and
a first conductive layer, located on a side of the active layer away from the base substrate, wherein the first conductive layer comprises a first conductive portion, a second reset signal line, and an enable signal line;
wherein an orthographic projection of the first conductive portion on the base substrate covers an orthographic projection of the third active portion on the base substrate, and the first conductive portion is configured to form a gate of the driving transistor;
an orthographic projection of the second reset signal line on the base substrate extends along the first direction and covers an orthographic projection of the fourth active portion on the base substrate, and a partial structure of the second reset signal line is configured to form a gate of the fourth transistor;
an orthographic projection of the enable signal line on the base substrate extends along the first direction and covers an orthographic projection of the fifth active portion on the base substrate, and a partial structure of the enable signal line is configured to form a gate of the fifth transistor;
the orthographic projection of the enable signal line on the base substrate is located between the orthographic projection of the first conductive portion on the base substrate and the orthographic projection of the second reset signal line on the base substrate;
wherein,
in the first direction, the orthographic projection of the fifth active portion on the base substrate is located between an orthographic projection of at least a partial structure of the third active portion on the base substrate and the orthographic projection of the fourth active portion on the base substrate; or,
in the first direction, the orthographic projection of the fourth active portion on the base substrate is located between an orthographic projection of at least a partial structure of the third active portion on the base substrate and the orthographic projection of the fifth active portion on the base substrate.

19. The display panel according to claim 2, wherein a square resistance of the second conductive layer is greater than a square resistance of the third conductive layer, and the display panel further comprises: a first initial routing line and a second initial routing line;
wherein, orthographic projections of the first initial routing line and the second initial routing line on the base substrate extend along the first direction, and are located on a side, in the second direction, of the orthographic projections of the first initial connection line and the second initial connection line on the base substrate, the first initial routing line connects multiple first initial connection lines, and the second initial routing line connects multiple second initial connection lines.

20. The display panel according to claim 19, further comprising a pixel driving circuit and a gate driving circuit;
wherein the orthographic projection of the second initial routing line on the base substrate is located on a side of the orthographic projection of the first initial routing line on the base substrate away from the orthographic projections of the first initial connection line and the second initial connection line on the base substrate;
the third conductive layer further comprises:
a plurality of gate line access lines, wherein orthographic projections of the gate line access lines on the base substrate extend along the first direction and are spaced apart along the second direction, and the gate line access lines are connected between the gate driving circuit and the pixel driving circuit.

21. The display panel according to claim 1, further comprising a gate driving circuit and a plurality of pixel driving circuits;
wherein the display panel further comprises:
a fourth conductive layer, located on a side of the base substrate, wherein the fourth conductive layer comprises a plurality of data lines, the data lines are configured to provide data signal to the pixel driving circuits, orthographic projections of the data lines on the base substrate extend along the second direction and are spaced apart along the first direction;
an electrode layer, located on a side of the fourth conductive layer away from the base substrate, wherein the electrode layer comprises a plurality of electrode portions; and
a pixel definition layer, located on a side of the electrode layer away from the base substrate, wherein a plurality of pixel openings are formed on the pixel definition layer and are arranged corresponding to the electrode portions, and an orthographic projection of a pixel opening on the base substrate coincide with an orthographic projection of a corresponding electrode portion on the base substrate;
wherein an orthographic projection of part of the electrode portions on the base substrate overlap with orthographic projections, on the base substrate, of two data lines adjacent in the first direction, and the orthographic projections, on the base substrate, of the two data lines adjacent in the first direction are respectively arranged close to two sides, in the first direction, of the orthographic projection of an overlapping electrode portion on the base substrate;
the fourth conductive layer further comprises:
an analog data line, wherein an orthographic projection of the analog data line on the base substrate extends along the second direction, and is located between an orthographic projection of the gate driving circuit on the base substrate and an orthographic projection of a data line closest to the gate driving circuit on the base substrate;
wherein orthographic projections, on the base substrate, of the analog data line and a data line adjacent to the analog data line overlap with an orthographic projection of an electrode portion on the base substrate, and in the first direction, the orthographic projections, on the base substrate, of the analog data line and the data line adjacent to the analog data line are respectively arranged close to two sides, in the first direction, of the orthographic projection of the overlapping electrode portion on the base substrate.

22. The display panel according to claim 21, further comprising a first initial routing line and a second initial routing line;
wherein, orthographic projections of the first initial routing line and the second initial routing line on the base substrate extend along the first direction, and are located on a side, in the second direction, of the orthographic projections of the first initial connection line and the second initial connection line on the base substrate, the first initial routing line connects multiple first initial connection lines, and the second initial routing line connects multiple second initial connection lines;
the orthographic projection of the second initial routing line on the base substrate is located on a side of the orthographic projection of the first initial routing line on the base substrate away from the orthographic projections of the first initial connection line and the second initial connection line on the base substrate;
the second initial signal line is connected to the analog data line, and the analog data line is connected to the plurality of second initial signal lines through a via.

23-25. (canceled)

26. A display device, comprising: the display panel according to claim 1.
